(19) United States
(12) Patent Application Publication
(10) Pub. No.: US 2025/0176294 A1
(43) Pub. Date: May 29, 2025

(54) IMAGE SENSOR

(71) Applicant: SAMSUNG ELECTRONICS CO., LTD., Suwon-si (KR)

(72) Inventors: Jonghyeon NOH, Suwon-si (KR); Kook Tae Kim, Suwon-si (KR); Jingyun Kim, Suwon-si (KR)

(73) Assignee: SAMSUNG ELECTRONICS CO., LTD., Suwon-si (KR)

(21) Appl. No.: 18/782,992

(22) Filed: Jul. 24, 2024

(30) Foreign Application Priority Data
Nov. 29, 2023 (KR) 10-2023-0169754

(51) Int. Cl. H01L 27/146

(52) U.S. Cl. CPC H10F 39/807; H10F 39/802; H10F 39/811

(57) ABSTRACT

An image sensor is provided. The image sensor includes a substrate; and a pixel separation structure in the substrate, the pixel separation structure separating pixels of the image sensor from each other. The pixels include first and second pixels spaced apart from each other along a first direction. The pixel separation structure includes: first silicon-containing patterns surrounding each of the first and second pixels when viewed in a plan view and being spaced apart from each other; and a second silicon-containing pattern extending between the first and second pixels and connecting the first silicon-containing patterns to each other. The second silicon-containing pattern includes side portions adjoining the first silicon-containing patterns, and a connecting portion spaced apart from the first silicon-containing patterns and connecting the side portions.

### CROSS-REFERENCE TO RELATED APPLICATION

This U.S. non-provisional patent application claims priority under 35 U.S.C. § 119 to Korean Patent Application No. 10-2023-0169754, filed on Nov. 29, 2023, in the Korean Intellectual Property Office, the disclosure of which is hereby incorporated by reference in its entirety.

### BACKGROUND

The present disclosure relates to an image sensor.

An image sensor is a device to convert an optical image into an electric signal. The image sensor may be categorized into a charge coupled device (CCD) type, and a complementary metal oxide semiconductor (CMOS) type. The CMOS image sensor may be abbreviated as a CMOS image sensor (CIS). The CIS includes a plurality of two-dimensionally arranged pixels. Each of the plurality of pixels includes a photodiode (PD). The PD converts an incident light into an electric signal.

### SUMMARY

One or more embodiments provide to an image sensor capable of realizing clear image quality.

Problems to be solved are not limited to the problems mentioned above, and other problems not mentioned will be clearly understood by those skilled in the art from the description below.

According to an aspect of an embodiment, an image sensor includes: a substrate having a first surface and a second surface opposite to the first surface; and a pixel separation structure in the substrate, the pixel separation structure separating pixels of the image sensor from each other. The pixels include first and second pixels spaced apart from each other along a first direction. The pixel separation structure includes: first silicon-containing patterns surrounding each of the first and second pixels when viewed in a plan view and being spaced apart from each other; and a second silicon-containing pattern extending between the first and second pixels and connecting the first silicon-containing patterns to each other. The second silicon-containing pattern includes side portions adjoining the first silicon-containing patterns, and a connecting portion spaced apart from the first silicon-containing patterns and connecting the side portions.

According to an aspect of an embodiment, an image sensor includes: a substrate having a first surface and a second surface opposite to the first surface; a transistor on the first surface; and a pixel separation structure in the substrate, the pixel separation structure separating pixels of the image sensor from each other. The pixels include first to fourth pixels arranged in a clockwise direction. The pixel separation structure includes: first silicon-containing patterns surrounding the first to fourth pixels when viewed in a plan view and spaced apart from each other; a second silicon-containing pattern connecting the first silicon-containing patterns adjacent to each other; and a first buried insulating pattern spaced apart from the first silicon-containing patterns. The second silicon-containing pattern extends between the first buried insulating pattern and the first silicon-containing patterns. The first buried insulating pattern penetrates the second silicon-containing pattern between a corner of the first pixel and a corner of the third pixel adjacent thereto.

According to an aspect of an embodiment, an image sensor includes: a substrate having a first surface and a second surface opposite to the first surface; and a pixel separation structure in the substrate, the pixel separation structure separating pixels of the image sensor from each other. The pixels include first and second pixels spaced apart from each other in a first direction. The pixel separation structure includes: a first buried insulating pattern between the first and second pixels and defining a first empty space inside of the first buried insulating pattern, the first empty space being vertically elongated; a silicon-containing pattern covering an inner wall of the first buried insulating pattern in the first empty space, having a ‘U’-shaped cross-section, and defining a second empty space; and a second buried insulating pattern in the second empty space.

### BRIEF DESCRIPTION OF THE DRAWINGS

The above and other aspects and features will be more apparent from the following description of embodiments, taken in conjunction with the accompanying drawings. The accompanying drawings represent non-limiting, example embodiments as described herein.

FIG. 1 is a block diagram for illustrating an image sensor according to embodiments.

FIG. 2 is a circuit diagram of an active pixel sensor array of an image sensor according to embodiments.

FIG. 3A is a top plan view of an image sensor according to embodiments.

FIG. 3B is a cross-sectional view of the image sensor taken along lines A-A′, B-B′, and C-C′ of FIG. 3A according to embodiments.

FIG. 4 is an enlarged view of portion ‘P4’ in FIG. 3B according to embodiments.

FIG. 5A is a top view at a first level of the image sensor of FIG. 3B according to embodiments.

FIG. 5B is an enlarged view of portion ‘P5’ of FIG. 3B according to embodiments.

FIGS. 6A, 6B and 6C are enlarged views of portion ‘P6’ in FIG. 3B according to embodiments.

FIG. 7 is a cross-sectional view of the image sensor taken along lines A-A′, B-B′, and C-C′ of FIG. 3A according to embodiments.

FIG. 8 is a cross-sectional view of the image sensor taken along lines A-A′, B-B′, and C-C′ of FIG. 3A according to embodiments.

FIG. 9 is a top plan view of an image sensor according to embodiments.

FIG. 10 is a cross-sectional view of the image sensor taken along lines A-A′, B-B′, and C-C′ of FIG. 9 according to embodiments.

FIG. 11 is a cross-sectional view of the image sensor taken along lines A-A′, B-B′, and C-C′ of FIG. 9 according to embodiments.

FIGS. 12A, 13A, 14A, 15A, 16A, and 19A are plan views sequentially illustrating a process of manufacturing an image sensor having the top views of FIGS. 3A and 5A according to embodiments.

FIGS. 12B, 13B, 14B, 15B, 16B, 18B, 19B, 20A, 20B, 20C, 20D, 20E and 20F are cross-sectional views sequentially illustrating a process of manufacturing the image sensor of FIGS. 3A and 3B according to embodiments.

FIG. 17 is a top view of the image sensor at a first level of FIG. 16B according to embodiments.

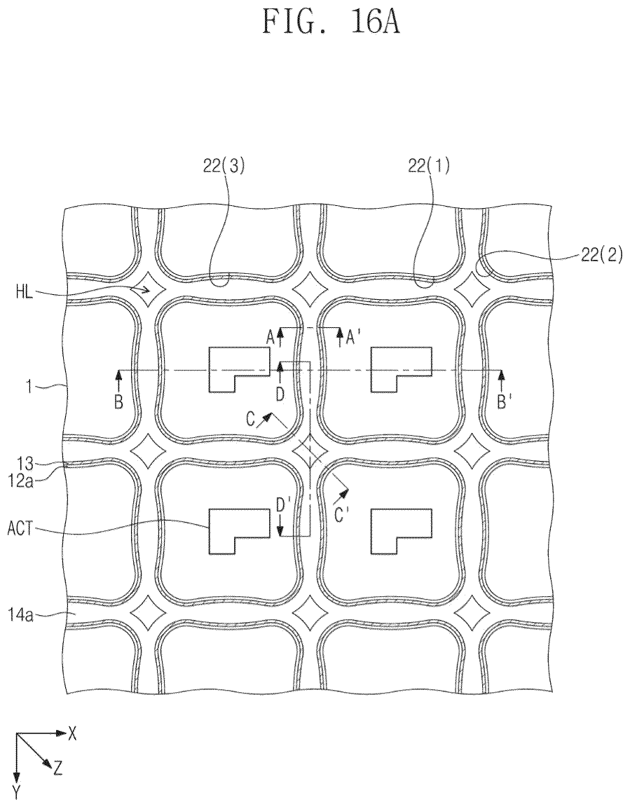

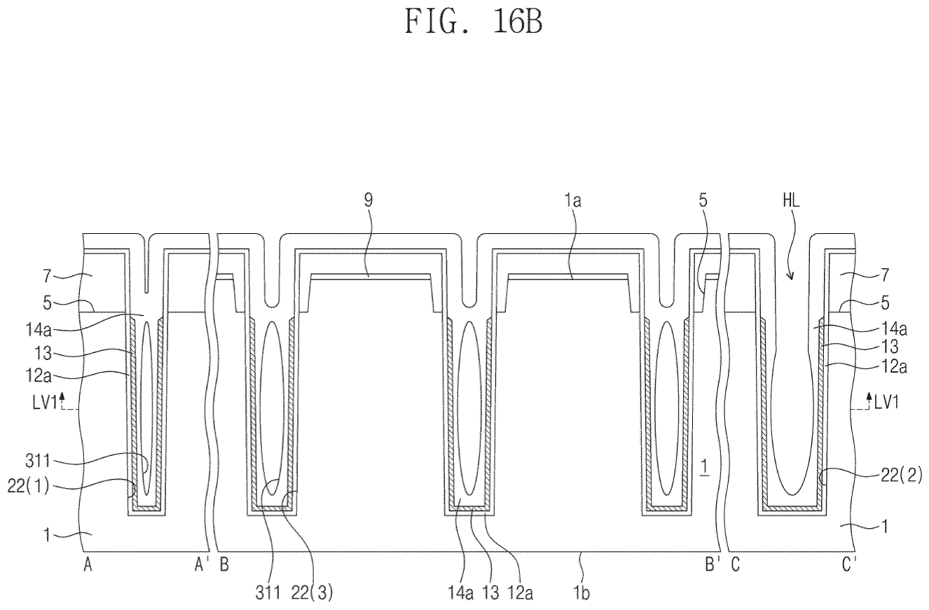

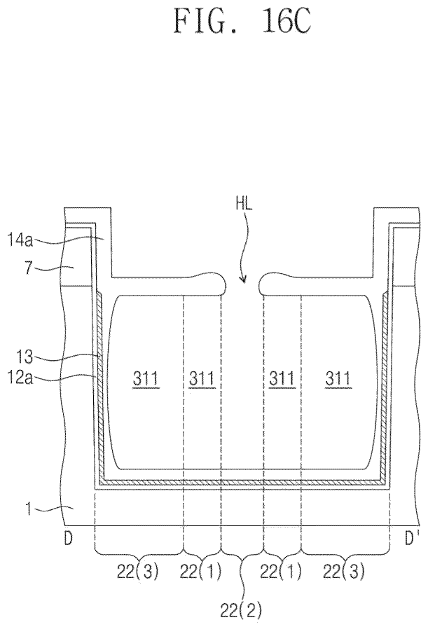

FIGS. 16C, 18A, 18B, and 19C are cross-sectional views illustrating a process of manufacturing an image sensor according to embodiments.

FIG. 21A is a top plan view of an image sensor according to embodiments.

FIG. 21B is a cross-sectional view of the image sensor taken along lines A-A′, B-B′, and C-C′ of FIG. 21A according to embodiments.

FIG. 21C is an enlarged view of portion ‘P7’ in FIG. 21B according to embodiments.

FIG. 21D is a top view at a first level of the image sensor of FIG. 21B according to embodiments.

FIG. 22 is a cross-sectional view of an image sensor according to embodiments.

FIG. 23 is a cross-sectional view of an image sensor according to embodiments.

### DETAILED DESCRIPTION

Hereinafter, embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

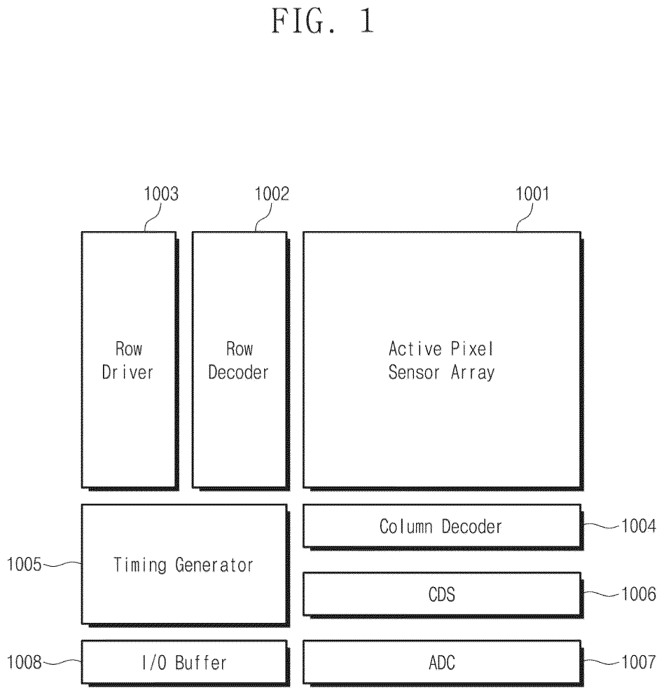

FIG. 1 is a block diagram for illustrating an image sensor according to embodiments.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output buffer (I/O buffer) 1008.

The active pixel sensor array 1001 may include a plurality of unit pixels, which are two-dimensionally arranged, and may be configured to convert an optical signal to an electrical signal. The active pixel sensor array 1001 may be driven by a plurality of driving signals, such as a pixel selection signal, a reset signal, and a charge transfer signal, which are transmitted from the row driver 1003. In addition, the converted electrical signal may be provided to the correlated double sampler 1006.

The row driver 1003 may be configured to provide a plurality of driving signals for driving the unit pixels of the active pixel sensor array 1001, based on the result decoded by the row decoder 1002. When the unit pixels are arranged in rows and columns, the driving signals may be provided to respective rows.

The timing generator 1005 may be configured to provide a timing signal and a control signal to the row decoder 1002 and the column decoder 1004.

The correlated double sampler 1006 may be configured to receive the electric signals generated by the active pixel sensor array 1001 and to perform a holding and sampling operation on the received electric signals. The correlated double sampler 1006 may perform a double sampling operation using a specific noise level and a signal level of the electric signal and then may output a difference level corresponding to a difference between the noise and signal levels.

The analog-to-digital converter 1007 may be configured to convert an analog signal, which indicates the difference level outputted from the correlated double sampler 1006, to a digital signal and to output the converted digital signal.

The input/output buffer 1008 may be configured to latch the digital signals and then to sequentially output the latched digital signals to an image signal processing unit, based on the result decoded by the column decoder 1004.

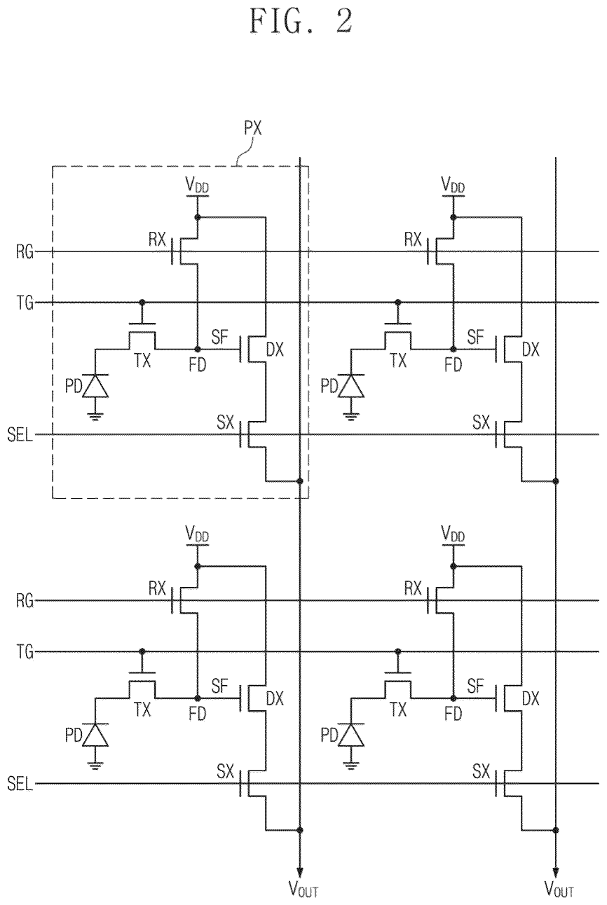

FIG. 2 is a circuit diagram of an active pixel sensor array of an image sensor according to embodiments.

Referring to FIGS. 1 and 2, the active pixel sensor array 1001 may include a plurality of unit pixels PX, which are arranged in a matrix shape. Each of the unit pixels PX may include a transfer transistor TX. Each of the unit pixels may further include logic transistors RX, SX, and DX. The logic transistors may include a reset transistor RX, a selection transistor SX, and a source follower transistor DX. The transfer transistor TX may include a transfer gate TG. Each of the unit pixels PX may further include a photoelectric converter PD and a floating diffusion region FD. The logic transistors RX, SX, and DX may be shared by a plurality of unit pixels PX.

The photoelectric converter PD may be configured to generate photocharges whose amount is proportional to an amount of externally incident light and to store the photocharges. The photoelectric converter PD may include a photo diode, a photo transistor, a photo gate, a pinned photo diode, or any combination thereof. The transfer transistor TX may be configured to transfer electric charges, which are generated in the photoelectric converter PD, to the floating diffusion region FD. The floating diffusion region FD may be configured to receive and cumulatively store the electric charges, which are generated in the photoelectric converter PD. The source follower transistor DX may be controlled, based on an amount of photocharges stored in the floating diffusion region FD.

The reset transistor RX may be configured to periodically discharge or reset the photocharges stored in the floating diffusion region FD. The reset transistor RX may include drain and source electrodes, which are connected to the floating diffusion region FD and a power voltage VDD, respectively. When the reset transistor RX is turned on, the power voltage VDD connected to the source electrode of the reset transistor RX may be applied to the floating diffusion region FD. Thus, when the reset transistor RX is turned on, the electric charges stored in the floating diffusion region FD may be discharged, that is, the floating diffusion region FD may be reset.

The source follower transistor DX including a source follower gate electrode SF may serve as a source follower buffer amplifier. The source follower transistor DX may be configured to amplify a variation in electric potential of the floating diffusion region FD and to output the amplified signal to an output line Vout.

The selection transistor SX including a selection gate electrode SEL may select one of the rows of the unit pixels PX, during reading operations. When the selection transistor SX is turned on, the power voltage VDD may be applied to a drain electrode of the source follower transistor DX.

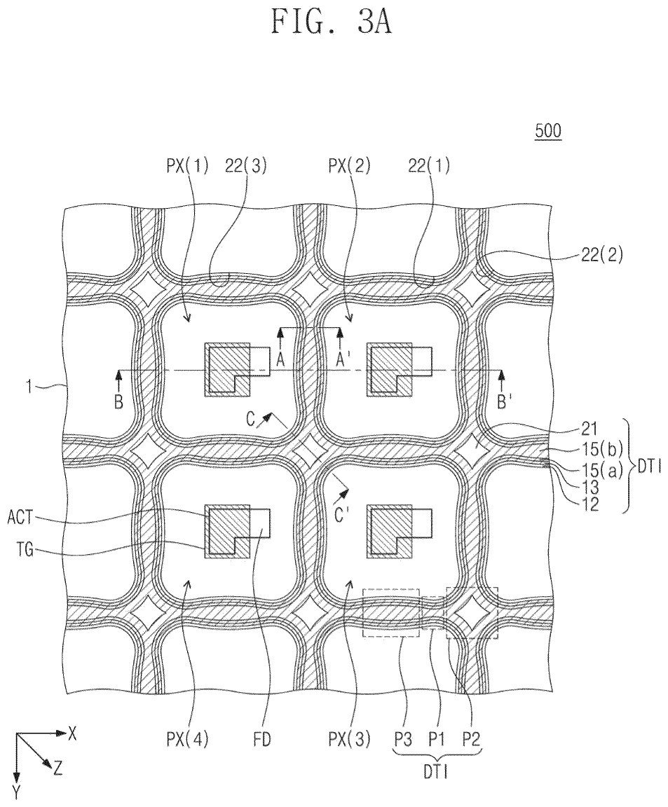

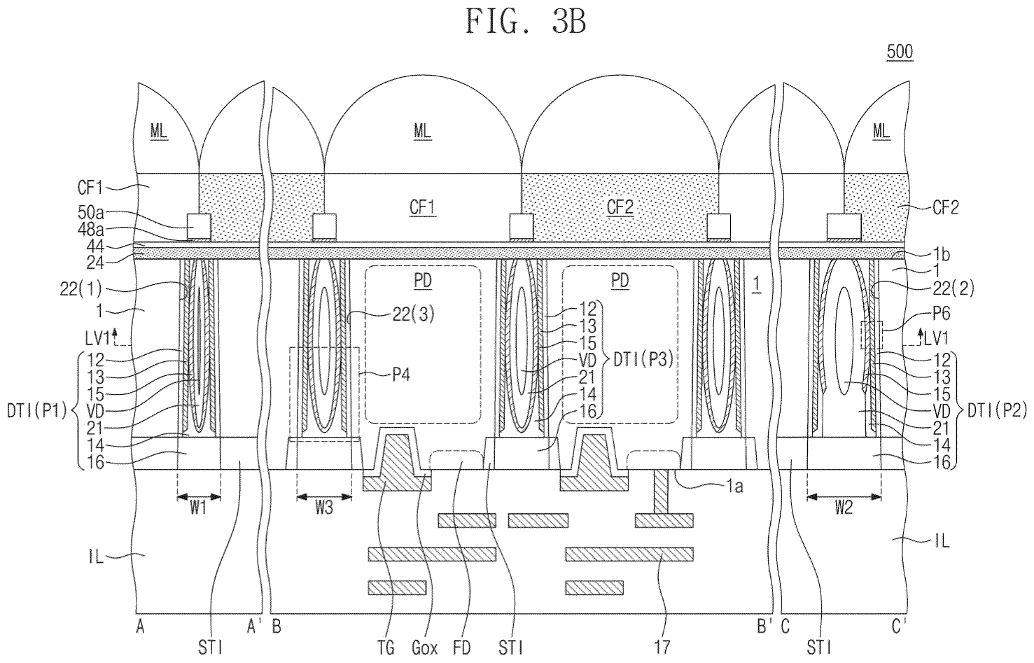

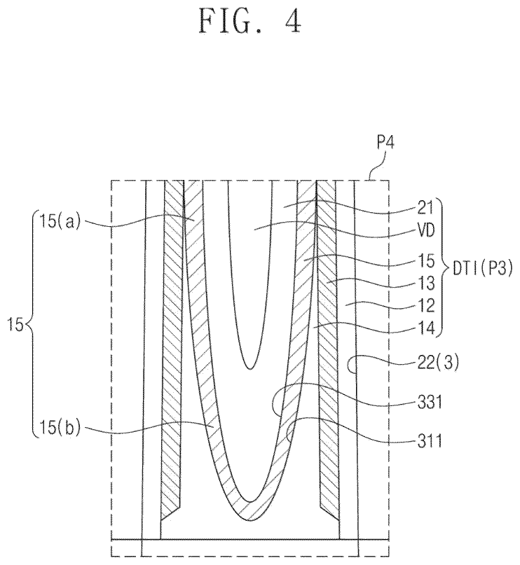

FIG. 3A is a top plan view of an image sensor according to embodiments. FIG. 3B is a cross-sectional view of the image sensor taken along lines A-A′, B-B′, and C-C′ of FIG. 3A according to embodiments. FIG. 4 is an enlarged view of portion ‘P4’ in FIG. 3B.

Referring to FIGS. 3A, 3B, and 4, an image sensor 500 according to embodiments includes a first substrate 1. The first substrate 1 may be, for example, a silicon single crystal wafer, a silicon epitaxial layer, or a silicon on insulator (SOI) substrate. The first substrate 1 may be doped with, for example, impurities of a first conductivity type. For example, the first conductivity type may be P-type. The first substrate 1 includes a front surface 1a and a back surface 1b that are opposite to each other. The front surface 1a may be referred to as the first surface 1a, and the back surface 1b may be referred to as a second surface 1b. The first substrate 1 may include a plurality of unit pixels PX.

The unit pixels PX may include first to fourth pixels PX(1) to PX(4) in a clockwise direction. The first and second pixels (PX(1) and PX(2)) may be arranged side by side in a first direction X. The fourth and first pixels PX(4) and PX(1) may be arranged side by side in a second direction Y that intersects the first direction X. The first and third pixels PX(1) and PX(3) may be arranged side by side in a third direction Z that simultaneously intersects the first direction X and the second direction Y.

A pixel separation part DTI may be disposed in the first substrate 1 to separate/define the unit pixels PX. The pixel separation part DTI may have a mesh shape when viewed in a plan view. The pixel separation part DTI may penetrate the first substrate 1. An aspect ratio of the pixel separation part DTI may be 50 to 300.

Referring to FIGS. 3A and 3B, the pixel separation part DTI may include first to third separation parts P1 to P3 when viewed in a plan view. The first separation part P1 may be interposed between the first and second pixels PX(1) and PX(2), and may be adjacent to edges (or corners) of the first and second pixels PX(1) and PX(2). The second separation part P2 is interposed between corners of the first and third pixels PX(1) and PX(3) adjacent to each other in the third direction Z. The third separation part P3 is interposed between centers of the first and second pixels PX(1) and PX(2). The first separation part P1 may have a first width W1 in the first direction X. The second separation part P2 may have a second width W2 in the third direction Z. The third separation part P3 may have a third width W3 in the first direction X. The third width W3 may be larger than the first width W1 and smaller than the second width W2. A sidewall of the pixel separation part DTI may have a convex-convex structure.

Referring to FIGS. 3A and 3B, the pixel separation part DTI is disposed in a deep trench 22 formed from the front surface 1a to the back surface 1b of the first substrate 1. The deep trench 22 includes first to third deep trenches 22(1) to 22(3). The first separation part P1 is disposed in the first deep trench 22(1). The second separation part P2 is disposed in the second deep trench 22(2). The third separation part P3 is disposed in the third deep trench 22(3).

Referring to FIGS. 3A, 3B, and 4, each of the first to third separation parts P1 to P3 includes an insulating liner pattern 12 covering an inner wall of the deep trench 22 and a first silicon-containing pattern 13 covering a side wall thereof. The insulating liner pattern 12 and the first silicon-containing pattern 13 may respectively surround the unit pixels PX when viewed in a plan. The first silicon-containing pattern 13 is formed in the form of a liner. The first silicon-containing pattern 13 may be formed of a boron-doped silicon layer. Alternatively, the first silicon-containing pattern 13 may be formed of boron-doped silicon germanium, SiC, or SiGe:C. The insulating liner pattern 12 may have a single-layer or multi-layer structure of at least one of SiO₂, Si₃N₄, SiCN, SiOCN, and SiON. The insulating liner pattern 12 may have a thickness of 10 Å to 2000 Å.

The first to third separation parts P1 to P3 may further include a first buried insulating pattern 14, a second silicon-containing pattern 15, a second buried insulating pattern 21, and a third buried insulating pattern 16. The second silicon-containing pattern 15 may be formed of a boron-doped or undoped silicon layer. Alternatively, the second silicon-containing pattern 15 may be formed of silicon germanium, SiC, or SiGe:C doped or undoped with boron.

The insulating liner pattern 12, the first buried insulating pattern 14, the second buried insulating pattern 21, and the third buried insulating pattern 16 may be formed of an insulating material having a refractive index different from that of the first silicon-containing pattern 13. Each of the first buried insulating pattern 14 and the second buried insulating pattern 21 may have a single-layer or multi-layer structure of at least one of High Aspect Ratio Process (HARP) oxide (i.e., thermal non-plasma-based chemical vapor deposition (CVD) oxide), High density plasma (HDP) oxide, Plasma-enhanced tetraethyl-orthosilicate (PE-TEOS), Low temperature oxide (LTO), Medium temperature oxide (MTO), and High temperature oxide (HTO). The third buried insulating pattern 16 may have a single-layer or multi-layer structure of at least one of ALD oxide, Flowable Chemical Vapor Deposition (FCVD) oxide, Tonen SilaZene (TOSZ), HDP oxide, HARP oxide, and PE-TEOS.

Referring to FIGS. 3A, 3B, and 4, the first buried insulating pattern 14 covers an upper sidewall and a lower sidewall of the first silicon-containing pattern 13. Alternatively, the first buried insulating pattern 14 may cover only the lower sidewall of the first silicon-containing pattern 13. In this regard, the first buried insulating pattern 14 may have a first empty space 311 therein, and a sidewall of a middle portion of the first silicon-containing pattern 13 may be exposed to the first empty space 311 of the first buried insulating pattern 14. That is, the first buried insulating pattern 14 may expose the sidewall of the middle portion of the first silicon-containing pattern 13 without covering it. In the first deep trench 22(1) and the third deep trench 22(3), the first buried insulating pattern 14 may be divided into a plurality of pieces. An upper surface of the first buried insulating pattern 14 adjacent to the front surface 1a of the first substrate 1 may be concave.

Referring to FIGS. 3A, 3B, and 4, the second silicon-containing pattern 15 is disposed in the first empty space 311 of the first buried insulating pattern 14. The second silicon-containing pattern 15 may have a ‘U’-shaped cross section. The second silicon-containing pattern 15 may connect the first silicon-containing patterns 13 facing each other in the first deep trench 22(1) and the third deep trench 22(3). The second silicon-containing pattern 15 may be formed in a liner shape. The second silicon-containing pattern 15 may include a side part 15(a) in contact with the first silicon-containing pattern 13, and a connecting part 15(b) that is spaced apart from the first silicon-containing pattern 13 and connects the side parts 15(a). Each of the side parts 15(a) may be curved to protrude toward a side surface of the substrate and have an arc shape. The connecting part 15(b) is in contact with the first buried insulating pattern 14. The first buried insulating pattern 14 is interposed between the connecting part 15(b) and the first silicon-containing pattern 13. A lower surface of the connecting part 15(b) may protrude toward the front surface 1a of the first substrate 1 and may be rounded.

A negative bias voltage may be applied to the first silicon-containing pattern 13 and the second silicon-containing pattern 15. The first silicon-containing pattern 13 may serve as a common bias line. As a result, holes that may exist on the surface of the first substrate 1 in contact with the pixel separation parts DTI may be trapped, thereby improving dark current characteristics.

In the section C-C′ of FIG. 3B, the second silicon-containing pattern 15 does not connect the first silicon-containing patterns 13 facing each other in the second deep trench 22(2).

Referring to FIGS. 3A, 3B and 4, the second silicon containing pattern 15 in the first deep trench 22(1) and the third deep trench 22(3) may have a hollow shell shape. That is, the second silicon-containing pattern 15 may have a second empty space 331. A second buried insulating pattern 21 is disposed in the second empty space 331 of the second silicon-containing pattern 15. The second buried insulating pattern 21 may penetrate the second silicon-containing pattern 15 in the second deep trench 22(2) in the C-C′ cross section of FIG. 3B. A void region VD may be disposed inside the second buried insulating pattern 21.

In the image sensor 500, the second silicon-containing pattern 15 does not exist in a center of the second deep trench 22(2) having the widest width, and instead, a second buried insulating pattern (21) and a void region (VD) may be disposed therein. In this regard, the second silicon-containing pattern 15 may include two segments that are separated from each other, each of which faces the void region VD. As a result, photosorption by the second silicon-containing pattern 15 may be minimized, thereby reducing optical loss.

The third buried insulating pattern 16 is disposed between the front surface 1a of the first substrate 1 and the first buried insulating pattern 14. The third buried insulating pattern 16 may be spaced apart from the first and second silicon-containing patterns 13 and 15.

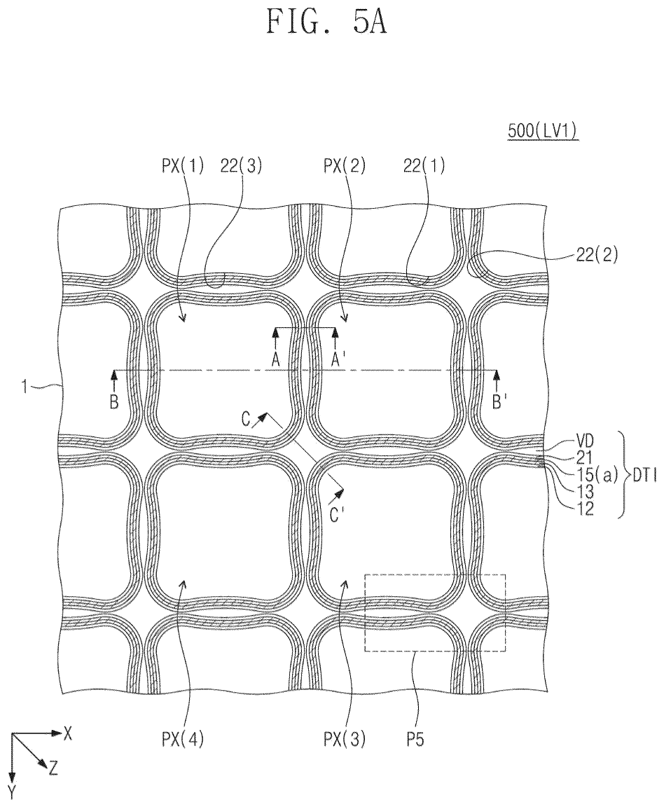

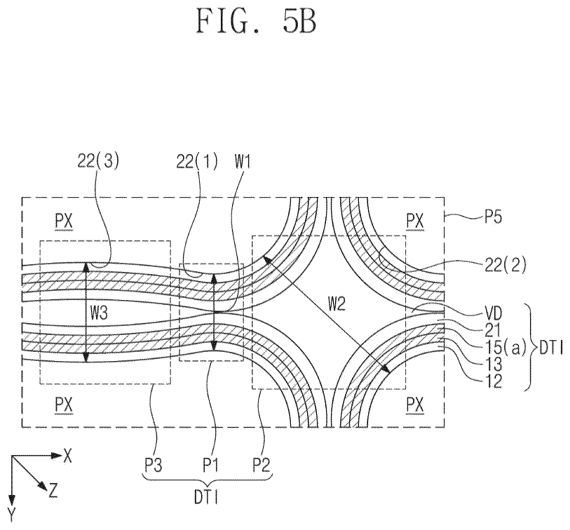

FIG. 5A is a top view at a first level LV1 of the image sensor of FIG. 3B. A cross-sectional view of the image sensor of FIG. 5A cut along lines A-A′, B-B′, and C-C′ may be the same as FIG. 3B. FIG. 5B is an enlarged view of portion ‘P5’ of FIG. 5A.

Referring to FIGS. 3B, 5A, and 5B, the void region VD at the first level LV1 is present in all of the first to third separation parts P1 to P3 of the pixel separation part DTI and may be connected to each other. In the present example, an upper end of the void region VD may be spaced apart from the back surface 1b of the first substrate 1. A thickness of the second buried insulating pattern 21 in the second deep trench 22(2) may be greater than a thickness of the second buried insulating pattern 21 in the first deep trench 22(1) and the third deep trench 22(3).

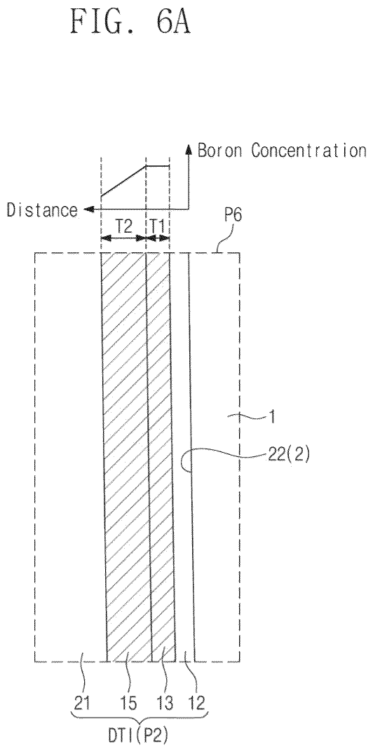

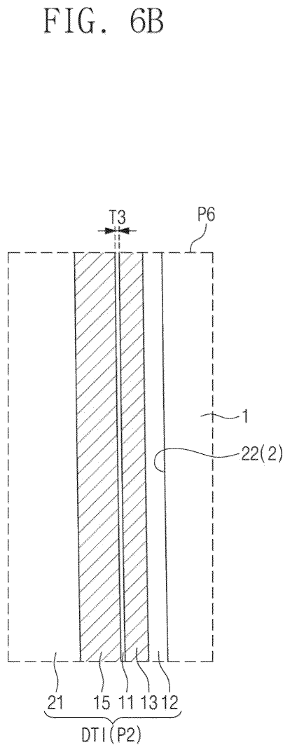

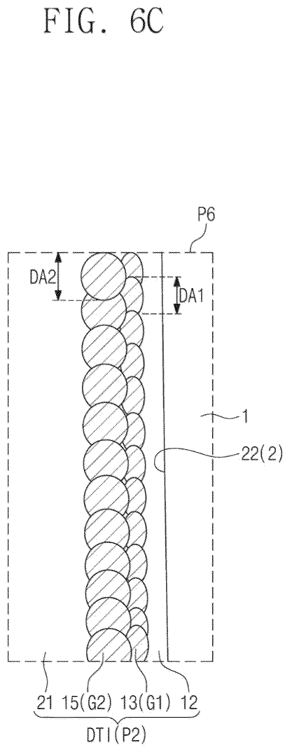

FIGS. 6A to 6C are enlarged views of portion ‘P6’ in FIG. 3B according to embodiments.

Referring to FIG. 6A, the first silicon-containing pattern 13 may have a first thickness T1. The second silicon-containing pattern 15 may have a second thickness T2. The second thickness T2 may be the same as or different from the first thickness T1. For example, the second thickness T2 may be greater than the first thickness T1. The first silicon-containing pattern 13 may be doped with a first impurities (e.g., boron) at a first concentration. The second silicon-containing pattern 15 may be doped with a first impurities (e.g., boron) at a second concentration or may not be doped. The second concentration may be equal to or less than the first concentration. In the second silicon-containing pattern 15, the concentration of the first impurities (e.g., boron) may decrease as distance from the insulating liner pattern 12 increases. As the doping concentration of boron in the second silicon-containing pattern 15 decreases, an amount of light absorbed by the second silicon-containing pattern 15 may be reduced. Accordingly, light loss may be reduced, thereby improving light-receiving rate and improving image quality.

Alternatively, referring to FIG. 6B, a natural oxide layer 11 may be disposed between the first silicon-containing pattern 13 and the second silicon-containing pattern 15. The natural oxide layer 11 may have a third thickness T3. The third thickness T3 may preferably be 1 Å to 5 Å. As the third thickness T3 is as thin as 5 Å or less, the first silicon-containing pattern 13 and the second silicon-containing pattern 15 may be electrically connected to each other.

Alternatively, referring to FIG. 6C, the first silicon-containing pattern 13 may include first silicon grains G1 having a first average diameter DA1. The second silicon-containing pattern 15 may include second silicon grains G2 having a second average diameter DA2. The second average diameter DA2 may be larger than the first average diameter DA1. A density of the first silicon grains G1 in the first silicon-containing pattern 13 may be greater than a density of the second silicon grains G2 in the second silicon-containing pattern 15.

In the unit pixels PX, photoelectric converters PD may be disposed in the first substrate 1, respectively. The photoelectric converters PD may be doped with impurities of a second conductivity type opposite to the first conductivity type. The second conductivity type may be, for example, N-type. The N-type impurities doped in the photoelectric converter PD may form a PN junction with the P-type impurities doped in the surrounding first substrate 1 to provide a photodiode.

Device isolation parts STI adjacent to the front surface 1a may be disposed in the first substrate 1. The device isolation parts STI may have a single-layer or multi-layer structure of at least one of silicon oxide, silicon nitride, and silicon oxynitride. The device isolation parts STI may be penetrated by the pixel separation part DTI. The device isolation parts STI may define active regions ACT adjacent to the front surface 1a in each unit pixel PX. The active regions ACT may be provided for the transistors TX, RX, DX, and SX of FIG. 2.

A transfer gate TG may be disposed on the front surface 1a of the first substrate 1 in each unit pixel PX. A portion of the transfer gate TG may extend into the first substrate 1. The transfer gate TG may be a vertical type. Alternatively, the transfer gate TG may be a planar type that does not extend into the first substrate 1 and is flat. A gate insulating layer Gox may be interposed between the transfer gate TG and the first substrate 1. A floating diffusion region FD may be disposed in the first substrate 1 on one side of the transfer gate TG. For example, the floating diffusion region FD may be doped with impurities of the second conductivity type.

The image sensor 500 may be a backside illuminated image sensor. Light may be incident into the first substrate 1 through the back surface 1b of the first substrate 1. Electron-hole pairs may be formed at the PN junction by incident light. Electrons generated in this way may be moved to the photoelectric converter PD. When a voltage is applied to the transfer gate TG, the electrons may move to the floating diffusion region FD.

The front surface 1a may be covered with a first interlayer insulating layer IL. The first interlayer insulating layer IL may be formed as a multilayer layer and at least one layer may be selected from a silicon oxide layer, a silicon nitride layer, a silicon oxynitride layer, and a porous low-k dielectric layer. First wirings 17 may be disposed in the first interlayer insulating layer IL. The floating diffusion region FD may be connected to the first wirings 17.

A fixed charge layer 24 is disposed on the back surface 1b of the first substrate 1. The fixed charge layer 24 may be in contact with the back surface 1b of the first substrate 1. The fixed charge layer 24 may be formed of a single layer or a multilayer of a metal oxide layer or a metal fluoride layer containing oxygen or fluorine in an amount less than the stoichiometric ratio. Accordingly, the fixed charge layer 24 may have a negative fixed charge. The fixed charge layer 24 may be formed of a single layer or multiple layers of metal oxide or metal fluoride including at least one metal selected from the group including hafnium (Hf), zirconium (Zr), aluminum (Al), tantalum (Ta), titanium (Ti), yttrium, and lanthanoid. As a specific example, the fixed charge layer 24 may include a hafnium oxide layer and/or an aluminum oxide layer. Dark current and white spot may be improved by the fixed charge layer 24.

A first protective layer 44 may be stacked on the fixed charge layer 24. The first protective layer 44 may include at least one of PE-TEOS, SiOC, SiO₂, and SiN. The first protective layer 44 may function as an antireflection layer and/or a planarization layer.

Light-shielding grid patterns 48a may be disposed on the first protective layer 44. Low-refraction patterns 50a may be disposed on the light-shielding grid patterns 48a, respectively. The light-shielding grid pattern 48a and the low-refraction pattern 50a may overlap the pixel separation part DTI and may have a grid shape when viewed in a plan view. The light-shielding grid pattern 48a may include titanium, for example. The low-refractive patterns 50a may have the same thickness and may include the same organic material. The low-refractive pattern 50a may have a smaller refractive index than that of color filters CF1 and CF2. For example, the low-refractive pattern 50a may have a refractive index of about 1.3 or less. The light-shielding grid pattern 48a and the low-refractive pattern 50a may prevent crosstalk between adjacent unit pixels PX.

Color filters CF1 and CF2 may be disposed between the low-refractive patterns 50a. The color filters CF1 and CF2 may each have one of blue, green, and red. As another example, the color filters CF1 and CF2 may include other colors such as cyan, magenta, or yellow.

In the image sensor according to the present example, the color filters CF1 and CF2 may be arranged in a Bayer pattern. In another example, the color filters CF1 and CF2 may be arranged in a 2×2 arrangement of a tetra pattern, a 3×3 arrangement of a nona pattern, or a 4×4 arrangement of a hexadeca pattern.

Micro lenses ML may be disposed on the color filters CF1 and CF2, respectively. Alternatively, one micro lens ML may cover a plurality of color filters CF1 and CF2 all together. Edges of the micro lenses ML may be in contact with each other and connected.

In the image sensor 500 according to the present example, the first silicon-containing pattern 13 exists in the form of the liner in the pixel separation part DTI. Additionally, the second silicon-containing pattern 15 may be in contact with a portion of the first silicon-containing patterns 13 and connect the first silicon-containing patterns 13. As a result, the portion occupied by silicon in the pixel separation part DTI may be relatively small. As a result, the photosorption and light loss due to silicon may be reduced, and light sensitivity may be improved to implement an image sensor with clear image quality.

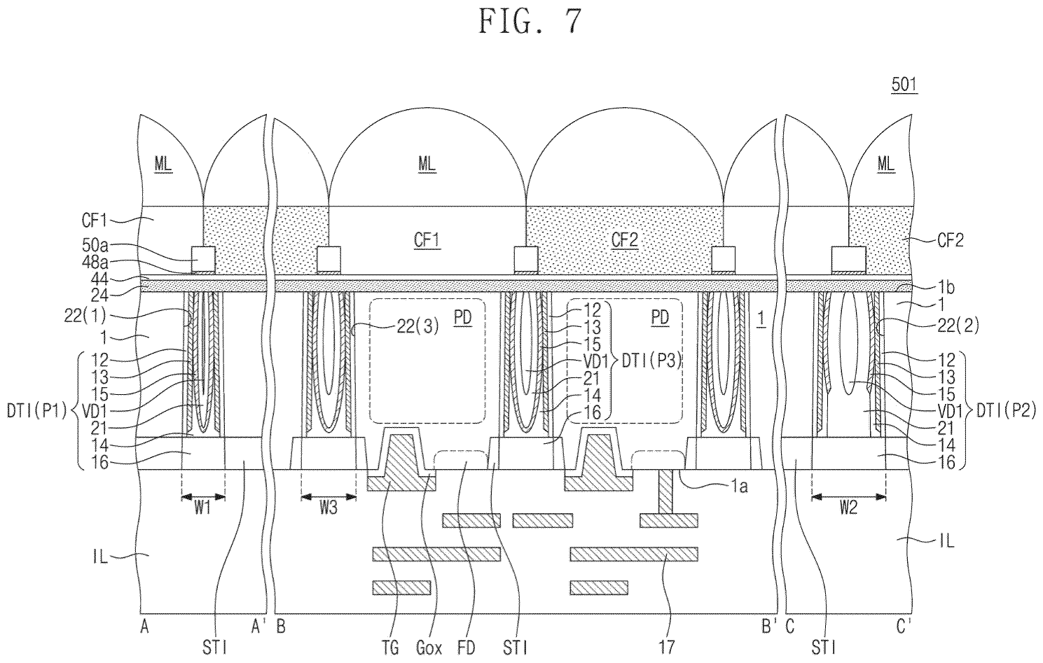

FIG. 7 is a cross-sectional view of the image sensor taken along lines A-A′, B-B′, and C-C′ of FIG. 3A according to embodiments.

Referring to FIG. 7, in an image sensor 501 according to the present example, a first void region VD1 may be disposed in the second buried insulating pattern 21, and an upper end of the first void region VD1 may be positioned at the same level as the back surface 1b of the first substrate. The upper end of the first void region VD1 may be defined by the fixed charge layer 24. Other structures may be the same/similar to those described with reference to FIG. 3B.

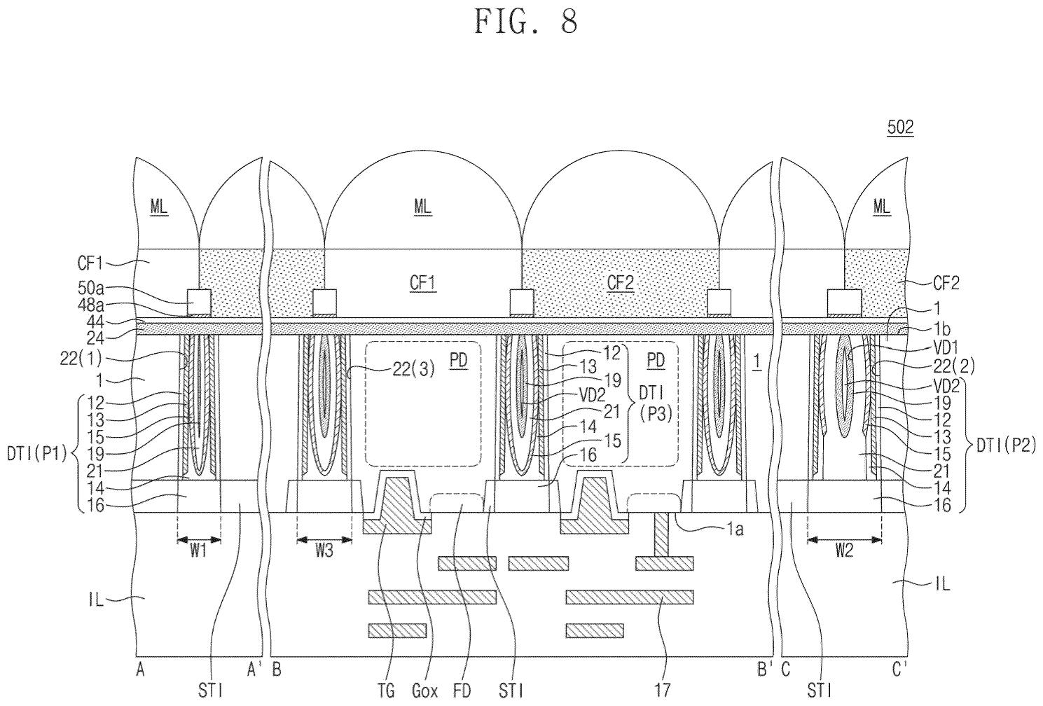

FIG. 8 is a cross-sectional view of the image sensor taken along lines A-A′, B-B′, and C-C′ of FIG. 3A according to embodiments.

Referring to FIG. 8, a remaining pattern 19 is disposed in the first void region VD1, in the structure of FIG. 7. That is, in an image sensor 502 according to the present example, the remaining pattern 19 is disposed in the second buried insulating pattern 21. The remaining pattern 19 may be formed of a material different from that of the second buried insulating pattern 21. An upper end of the remaining pattern 19 may be in contact with the fixed charge layer 24. The remaining pattern 19 may include the same material as the fixed charge layer 24. In this case, there may be no interface between the remaining pattern 19 and the fixed charge layer 24. An anti-reflection layer may be disposed on the back surface 1b of the first substrate 1, and the remaining pattern 19 may include the same material as the anti-reflection layer. Alternatively, the remaining pattern 19 may include metal. Accordingly, the pixel separation part DTI may be effective in preventing crosstalk between neighboring unit pixels PX. According to one example, the remaining pattern 19 may have a single-layer or multi-layer structure of at least one of Al₂O₃, TiO₂, HfOₓ, Al, W, Cu, Ag, and Si₃N₄. A second void region VD2 may be formed inside the remaining pattern 19 in the second deep trench 22(2) and the third deep trench 22(3).

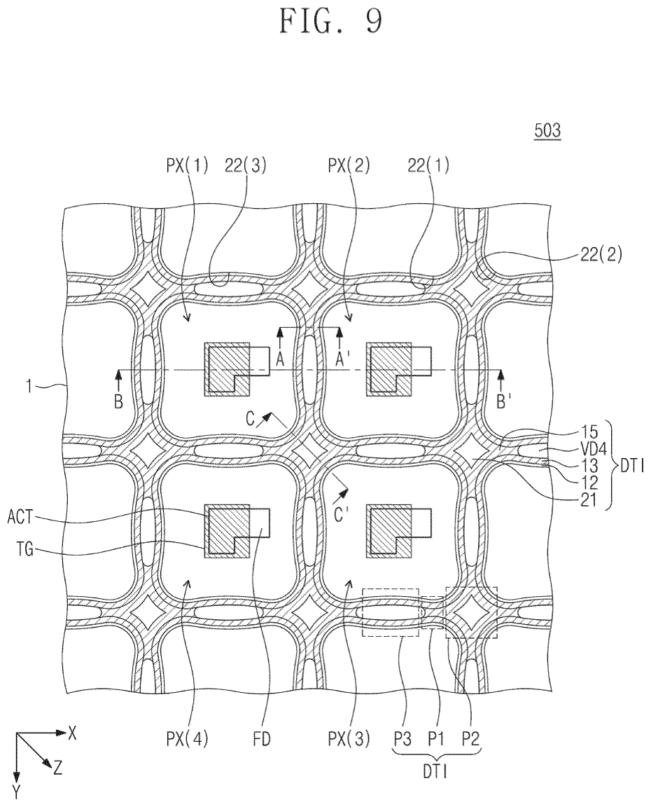

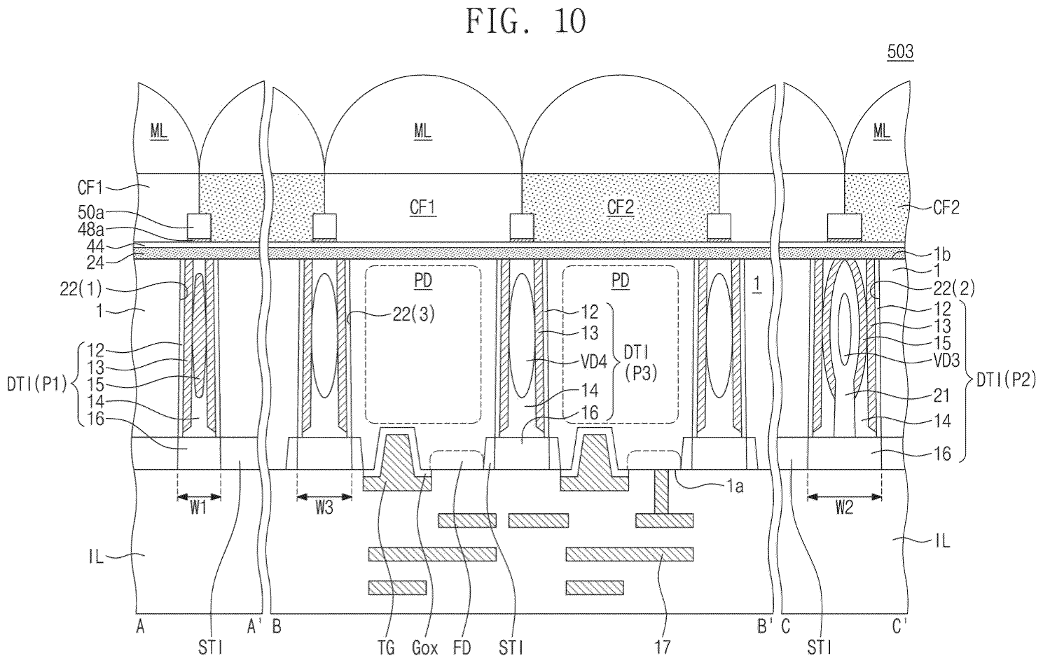

FIG. 9 is a top plan view of an image sensor according to embodiments. FIG. 10 is a cross-sectional view of the image sensor taken along lines A-A′, B-B′, and C-C′ of FIG. 9 according to embodiments.

Referring to FIGS. 9 and 10, in an image sensor 503 according to the present example, the pixel separation part DTI may have a cross-section with a structure that varies, and in this regard may have a cross-section of a different structure depending on a location. The second separation part P2 of the pixel separation part DTI may be the same/similar to FIG. 3B. The second separation part P2 of the pixel separation part DTI may include an insulating liner pattern 12, a first silicon-containing pattern 13, a first buried insulating pattern 14, a second silicon-containing pattern 15, a second buried insulating pattern 21, a third buried insulating pattern 16, and a third void region VD3. The first separation part P1 of the pixel separation part DTI may exclude the second buried insulating pattern 21 and the third void region VD3 of the second separation part P2. The first separation part P1 of the pixel separation part DTI may include first silicon-containing patterns 13 and a second silicon-containing pattern 15 connecting thereto. However, in the first separation part P1 of the pixel separation part DTI, the second silicon-containing pattern 15 may have an oval-shaped cross-section rather than a shell shape. When viewed in a plan view of FIG. 9, the second silicon-containing pattern 15 may have a hollow rhombus shape.

The third separation part P3 of the pixel separation part DTI may include first silicon-containing patterns 13 and a first buried insulating pattern 14, and may exclude a second silicon-containing pattern 15 and a second buried insulating pattern 21. In the third separation part P3 of the pixel separation part DTI, the first buried insulating pattern 14 may include a fourth void region VD4. The fourth void region VD4 may be separated from the third void region VD3 without being connected thereto. Other structures may be the same/similar to those described with reference to FIGS. 3A to 6C.

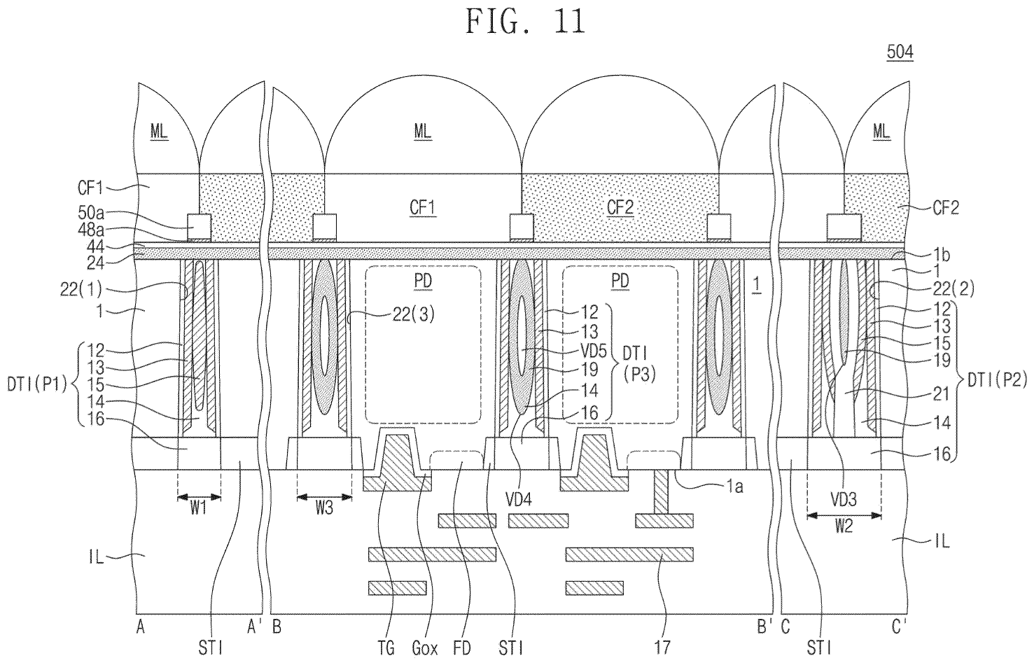

FIG. 11 is a cross-sectional view of the image sensor taken along lines A-A′, B-B′, and C-C′ of FIG. 9 according to embodiments.

Referring to FIG. 11, in an image sensor 504 according to the present example, in a structure of FIG. 10, a height of upper ends the third void region VD3 and the fourth void region VD4 is positioned at a level of the back surface 1b of the first substrate 1 and includes a remaining pattern 19 inserted into the third void region VD3 and the fourth void region VD4. The remaining pattern 19 may be the same/similar to that described with reference to FIG. 8. A fifth void region VD5 may be disposed in the remaining pattern 19 in the third separation part P3 of the pixel separation part DTI. Other structures may be the same/similar to those described with reference to FIGS. 9 and 10.

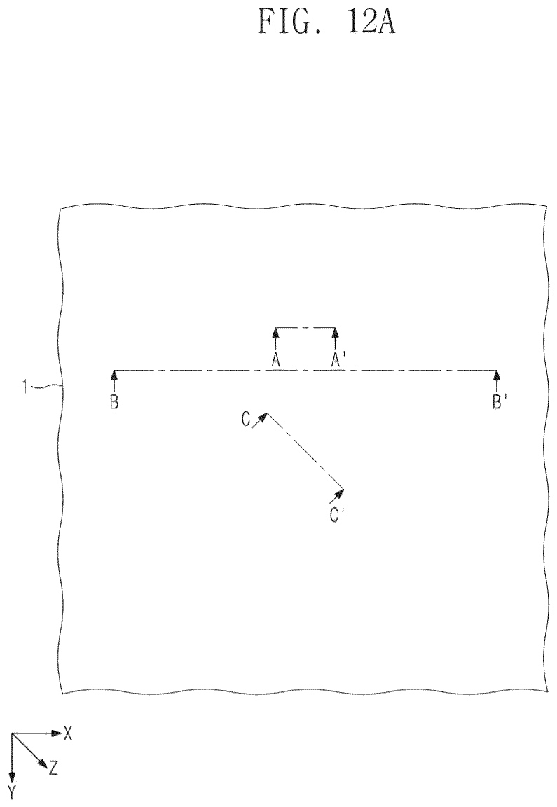

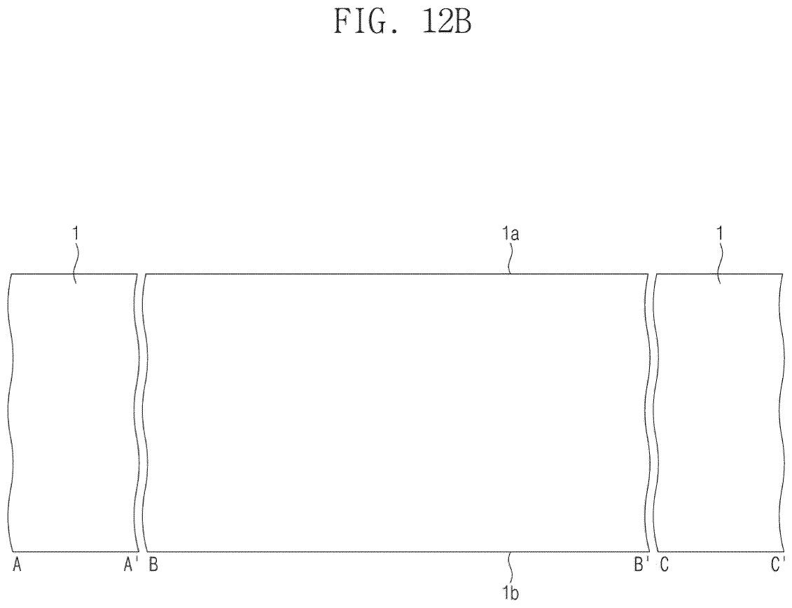

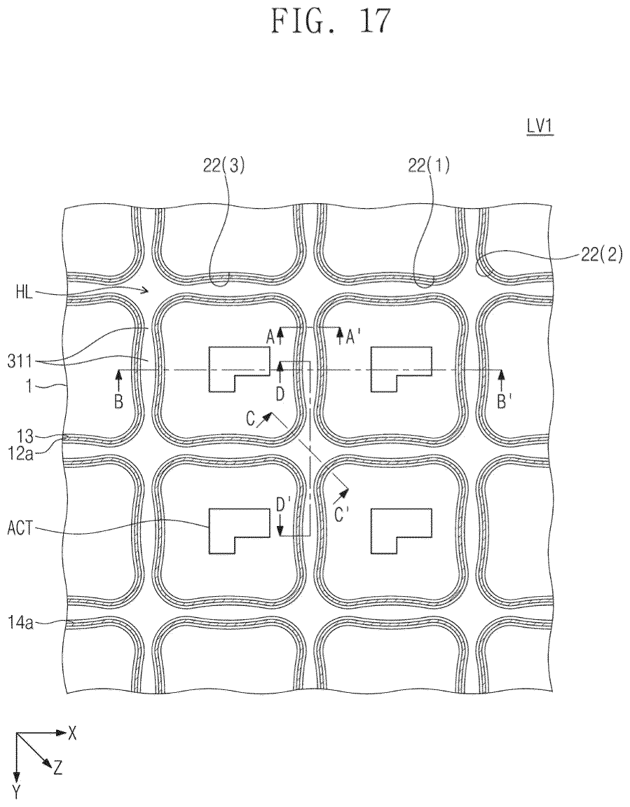

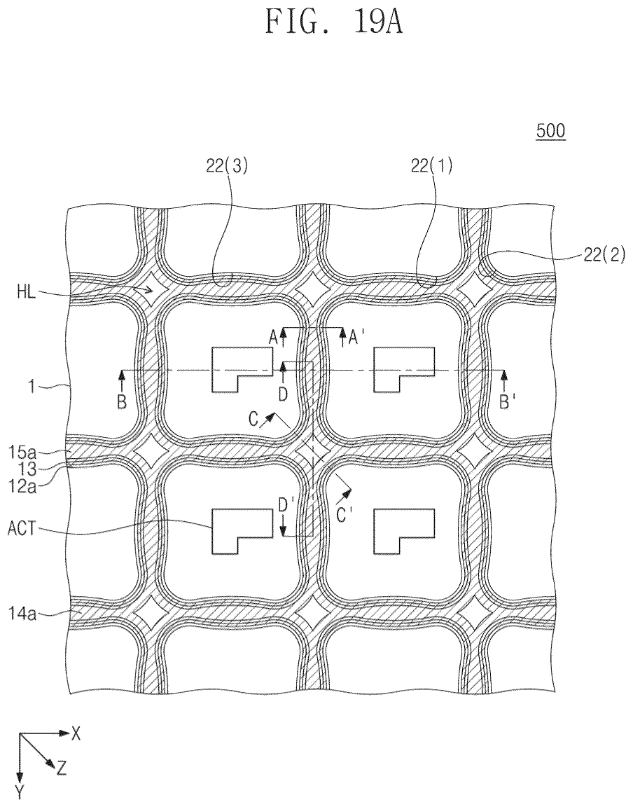

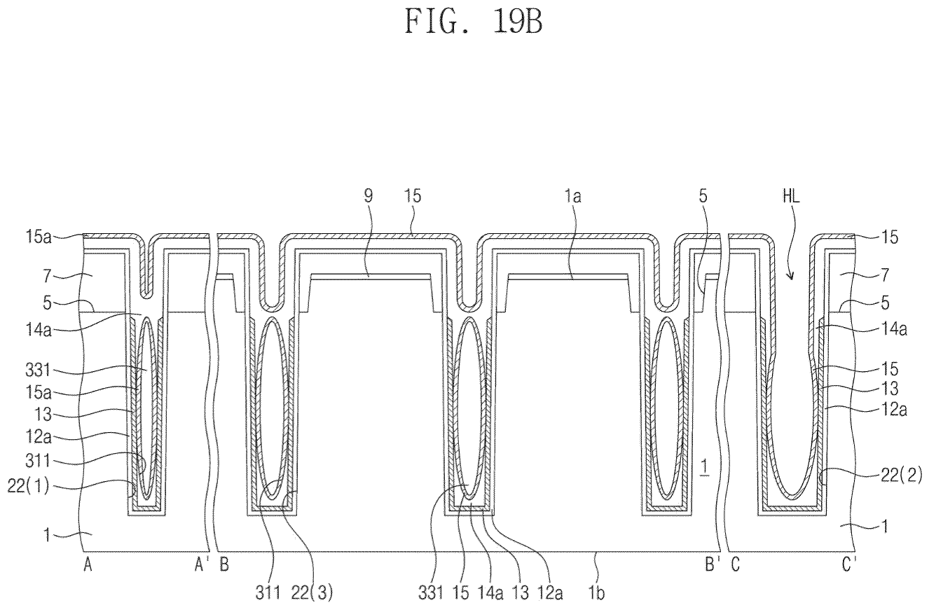

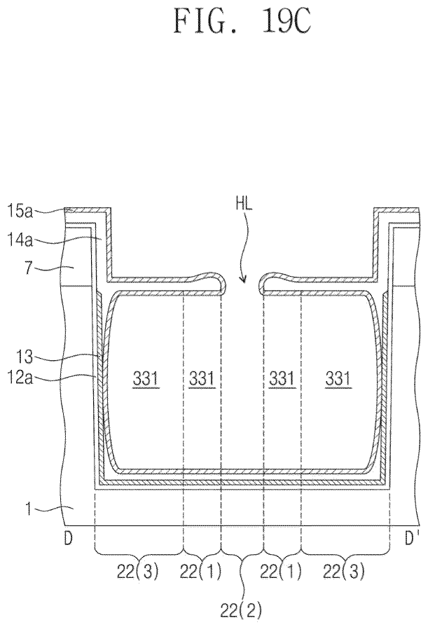

FIGS. 12A, 13A, 14A, 15A, 16A, and 19A are plan views sequentially illustrating a process of manufacturing an image sensor having the top views of FIGS. 3A and 5A. FIGS. 12B, 13B, 14B, 15B, 16B, 18B, 19B, and 20A to 20F are cross-sectional views sequentially illustrating a process of manufacturing the image sensor of FIGS. 3A and 3B. FIG. 17 is a top view of the image sensor at a first level of FIG. 16B. FIGS. 16C, 18B, and 19C are cross-sectional views illustrating a process of manufacturing an image sensor according to embodiments. FIGS. 12B, 13B, 14B, 15B, 16B, and 19B are cross-sectional views taken along lines A-A′, B-B′, and C-C′ of FIGS. 12A, 13A, 14A, 15A, 16A, and 19A, respectively. FIG. 16C is a cross-sectional view taken along line D-D′ of FIG. 16A. FIG. 19C is a cross-sectional view taken along line D-D′ of FIG. 19A.

Referring to FIGS. 12A and 12B, a first substrate 1 is prepared. The first substrate 1 may be, for example, a silicon single crystal wafer, a silicon epitaxial layer, or a silicon on insulator (SOI) substrate. The first substrate 1 may be doped with, for example, impurities of a first conductivity type. For example, the first conductivity type may be P type. The first substrate 1 includes a front surface 1a and a back surface 1b that are opposite to each other.

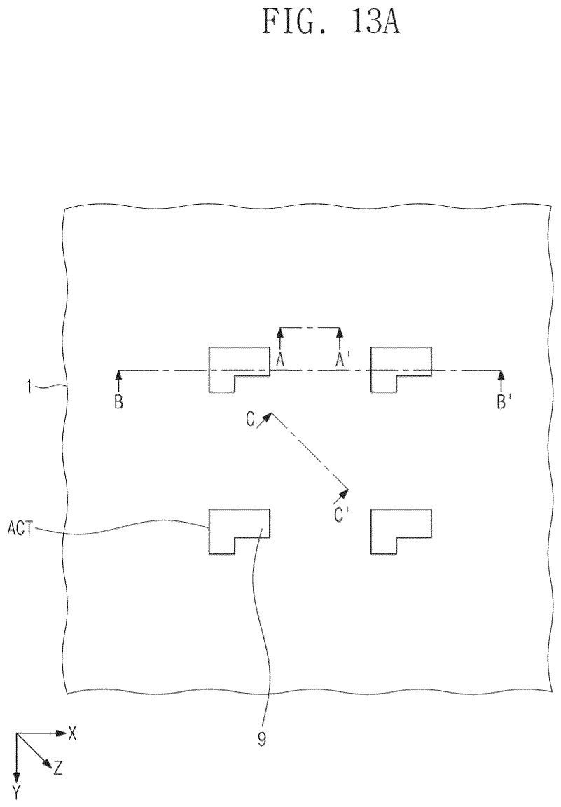

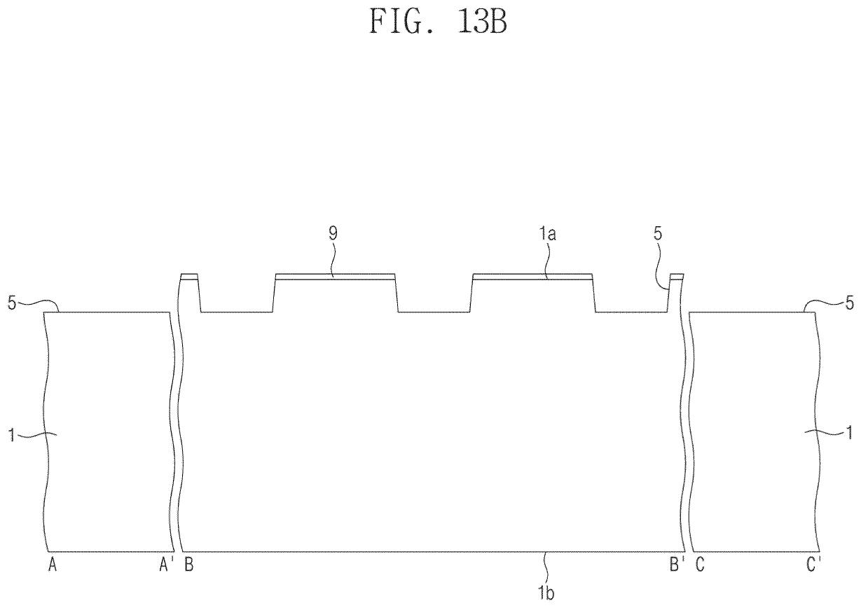

Referring to FIGS. 13A and 13B, a first mask pattern 9 is formed on the front surface 1a of the first substrate 1. The first mask pattern 9 may include, for example, a single-layer or multi-layer structure of at least one of silicon oxide, silicon nitride, and silicon oxynitride. The first mask pattern 9 may define positions of the active regions ACT of FIG. 3A on the front surface 1a. Using the first mask pattern 9 as an etch mask, the front surface 1a of the first substrate 1 is etched to form a shallow trench 5.

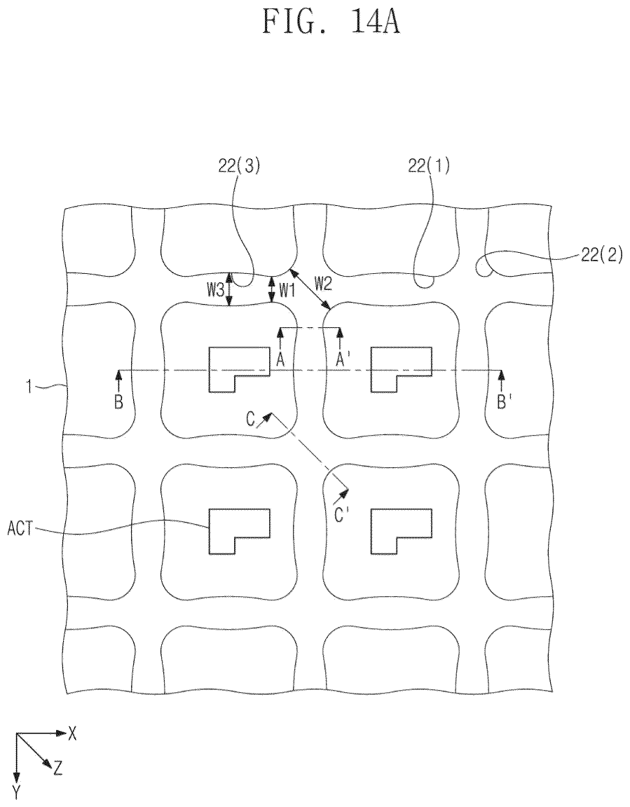

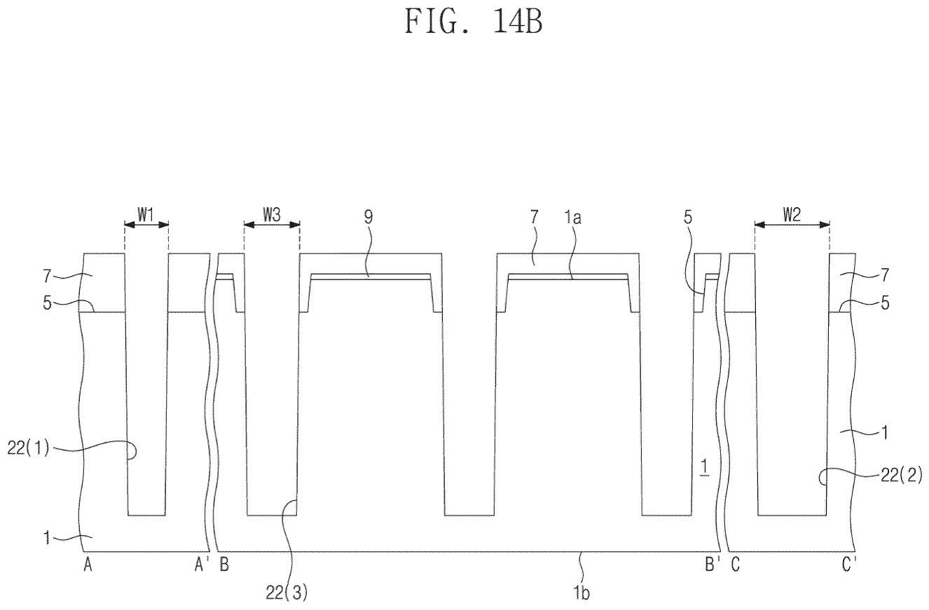

Referring to FIGS. 14A and 14B, a second mask pattern 7 is formed on the front surface 1a of the first substrate 1. The second mask pattern 7 may cover the first mask pattern 9 and partially fill the shallow trench 5. The second mask pattern 7 may define a location of a pixel separation part. The second mask pattern 7 may partially expose a lower surface of the shallow trench 5. The second mask pattern 7 may have a single-layer or multi-layer structure of at least one of silicon oxide, SiN, SiCN, and SiOCN. The first substrate 1 is etched using the second mask pattern 7 as an etch mask to form a deep trench 22.

When the deep trench 22 is formed, the deep trench 22 may be formed shown in FIG. 14A when viewed in a plan view, due to interference between etchants. That is, the deep trench 22 is formed to include first to third deep trenches 22(1) to 22(3). The first deep trench 22(1) may be disposed between the first and second pixels PX(1) and PX(2), and may be adjacent to edges of the first and second pixels PX(1) and PX(2). The second deep trench 22(2) is disposed between the first and third pixels PX(1) and PX(3). The third deep trench 22(3) is interposed between centers of the first and second pixels PX(1) and PX(2). The first deep trench 22(1) may be formed to have a first width W1 in the first direction X. The second deep trench 22(2) may be formed to have a second width W2 in the third direction Z. The third deep trench 22(3) may be formed to have a third width W3 in the first direction X. The third width W3 may be larger than the first width W1 and smaller than the second width W2.

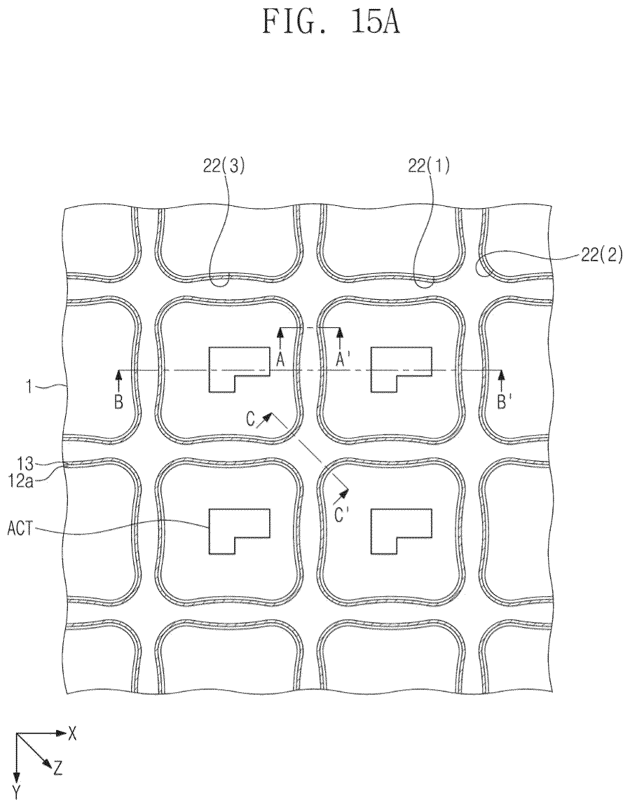

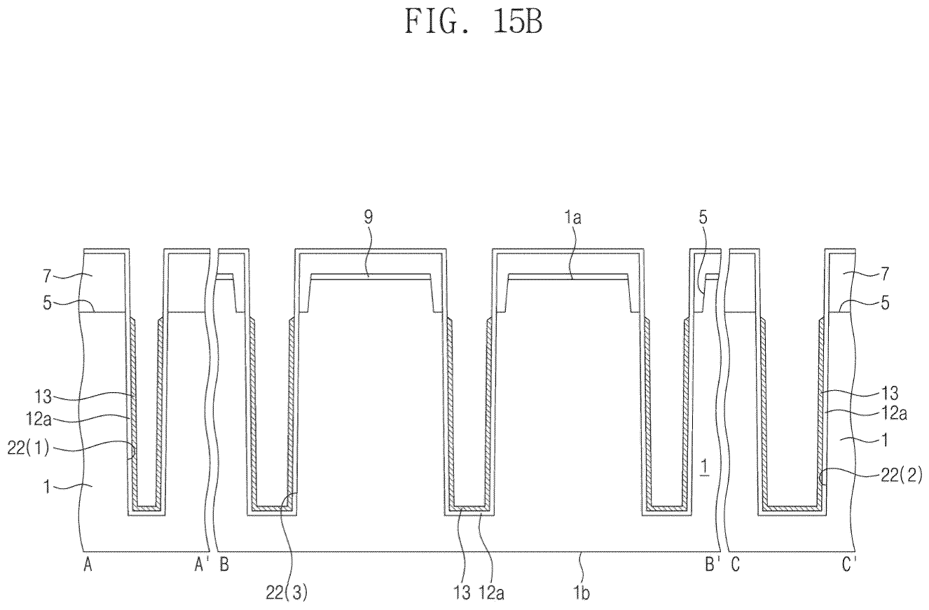

Referring to FIGS. 15A and 15B, an insulating liner layer 12a is conformally formed on the front surface 1a of the first substrate 1 where the deep trench 22 is formed using an atomic layer deposition (ALD) method. The insulating liner layer 12a may have a constant thickness regardless of a location thereof. The insulating liner layer 12a may be formed to have a single-layer or multi-layer structure of at least one of silicon oxide, silicon nitride, silicon oxynitride, and silicon carbonitride.

A first silicon-containing layer is conformally deposited on the insulating liner layer 12a and etched to form a first silicon-containing pattern 13 in the deep trench 22. Depositing and etching of the first silicon-containing layer may be performed sequentially in one process chamber. When forming the first silicon-containing layer, first impurities (e.g., boron) may be doped in-situ. An upper end of the first silicon-containing pattern 13 may be lower than a bottom surface of the shallow trench 5. The first silicon-containing layer may be an amorphous polysilicon layer, a polycrystalline silicon layer, a single crystalline silicon layer, SiGe, SiC, or SiGe:C. The first silicon-containing layer may be formed by ALD, CVD, or epitaxial deposition.

Referring to FIGS. 16A to 16C and 17, a first buried insulating layer 14a is disposed on the front surface 1a of the first substrate 1. The first buried insulating layer 14a may be formed through a deposition process with lower step coverage characteristics than that of an ALD process. For example, the first buried insulating layer 14a may be formed through a chemical vapor deposition (CVD) process such as low pressure CVD (LPCVD) or plasma enhanced CVD (PECVD). The first buried insulating layer 14a may cover an inner wall and a bottom surface of the deep trench 22. Alternatively, the first buried insulating layer 14a may cover only an upper inner wall of the deep trench 22 to block only an entrance of the deep trench 22, and may not cover the bottom surface of the deep trench 22. A thickness of the first buried insulating layer 14a may be variously changed depending on location. That is, the first buried insulating layer 14a may be formed relatively thick at the entrance and bottom of the deep trench 22, and the first buried insulating layer 14a may be formed relatively thin on the sidewalls of the deep trench 22. The first buried insulating layer 14a may block the entrances of the relatively narrow first deep trench 22(1) and the third deep trench 22(3) to form a first empty space 311 in the first buried insulating layer 14a. However, embodiments are not limited thereto and the entrance of the widest second deep trench 22(2) may be opened and not blocked by the first buried insulating layer 14a. Accordingly, a first hole HL may be formed in the first buried insulating layer 14a in the second deep trench 22(2). As illustrated in FIGS. 16C and 17, the first hole HL may be connected to the first empty space 311.

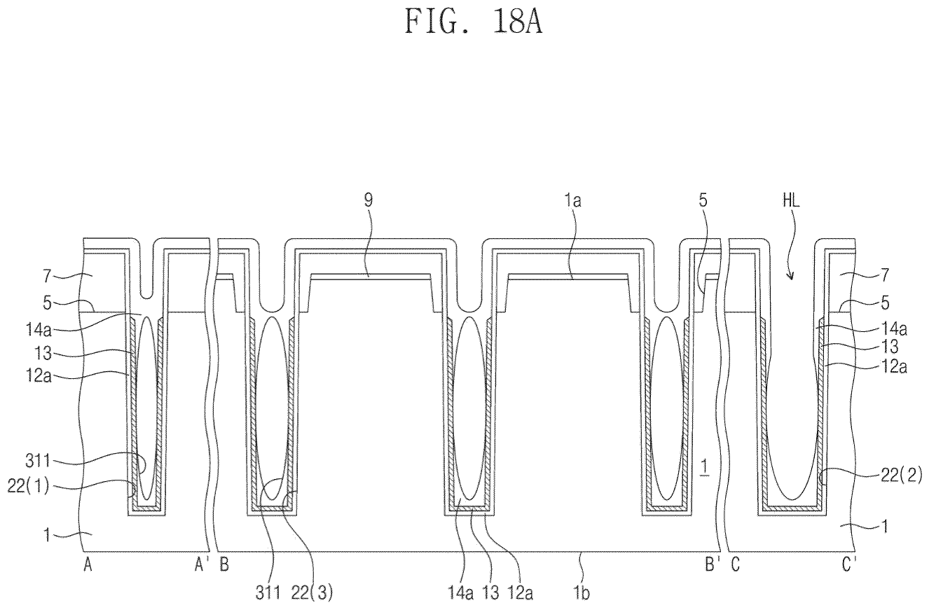

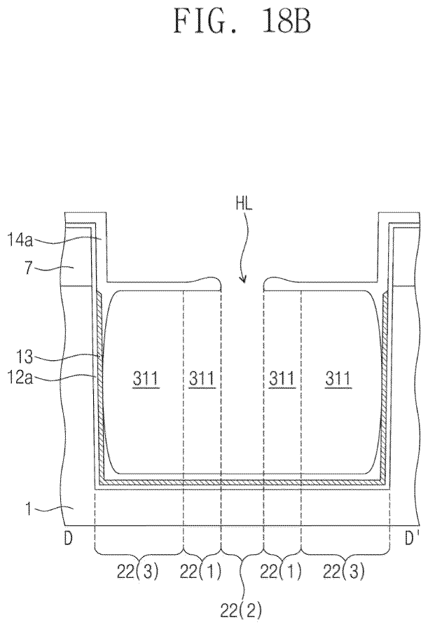

Referring to FIGS. 18A and 18B, an isotropic etching process is performed on the first buried insulating layer 14a. As a result, the entire surface of the first buried insulating layer 14a may be etched, thereby reducing a thickness of the first buried insulating layer 14a. Accordingly, a portion of a sidewall of the first silicon-containing pattern 13 may be exposed.

When the thickness is thinned or process time is reduced in a process of depositing the first buried insulating layer 14a of FIGS. 16A to 16C, a portion of the sidewall of the first silicon-containing pattern 13 may be exposed rather than covered, and in this case, the isotropic etching process for the first buried insulating layer 14a of FIGS. 18A and 18B may be omitted.

Referring to FIGS. 19A to 19C, the second silicon-containing layer 15a may be conformally deposited on the first buried insulating layer 14a. The second silicon-containing layer 15a may be formed by ALD. The second silicon-containing layer 15a may be formed to be in contact with the first silicon-containing pattern 13 in the deep trench 22. The second silicon-containing layer 15a may conformally cover an inner wall of the first hole HL, and may conformally cover the inner wall of the first buried insulating pattern 14 in the first empty space 311 through the first hole HL. The second silicon-containing layer 15a may be an amorphous polysilicon layer, a polycrystalline silicon layer, or a single crystalline silicon layer. When depositing the second silicon-containing layer 15a, boron may be doped in-situ. The second silicon-containing layer 15a is formed in a liner shape without filling the first empty space 311. As a result, a second empty space 331 defined by the second silicon-containing layer 15a is formed.

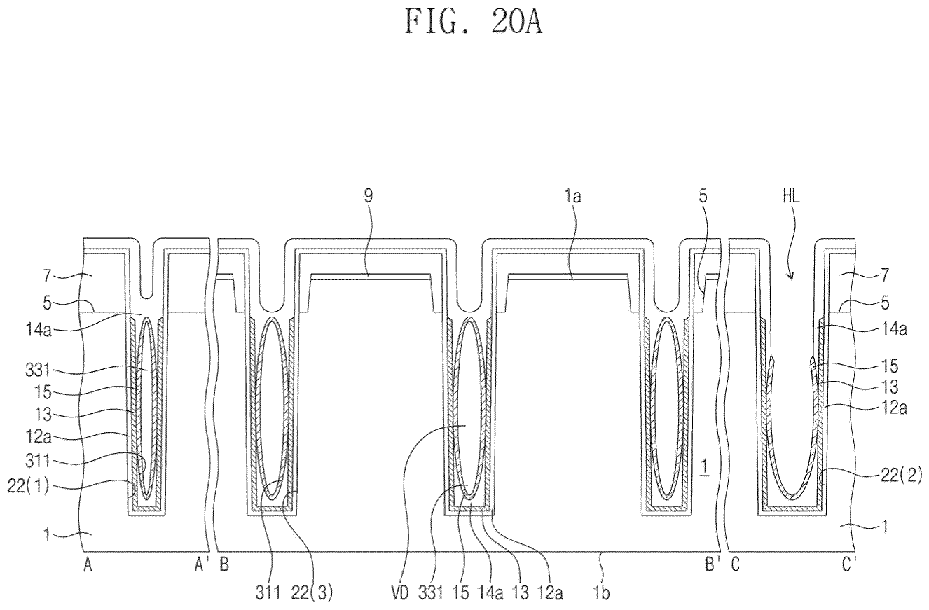

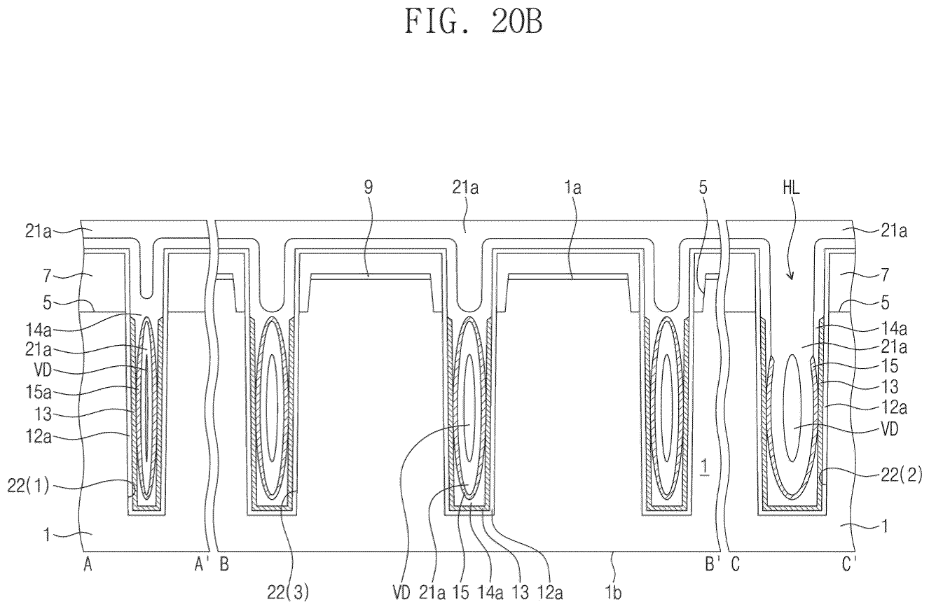

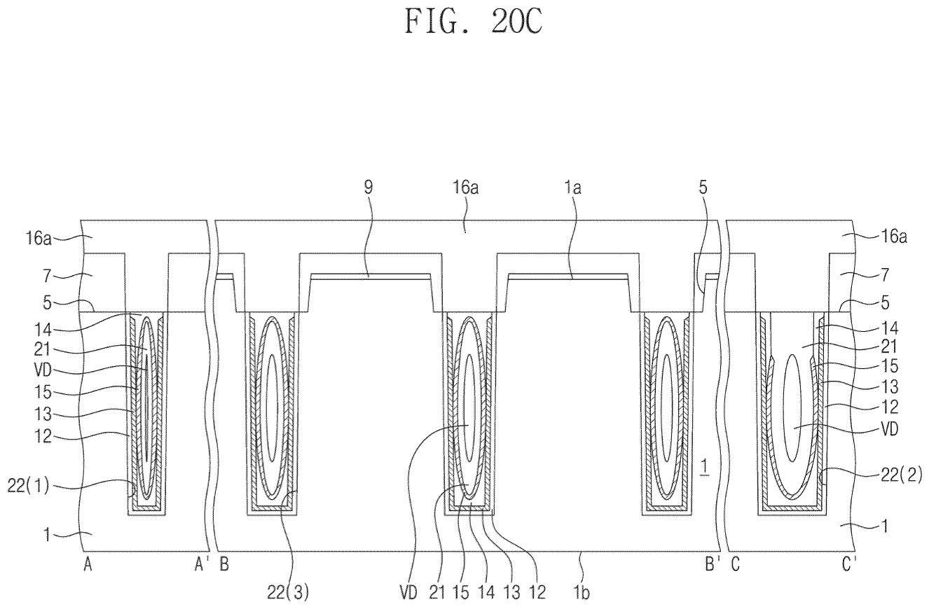

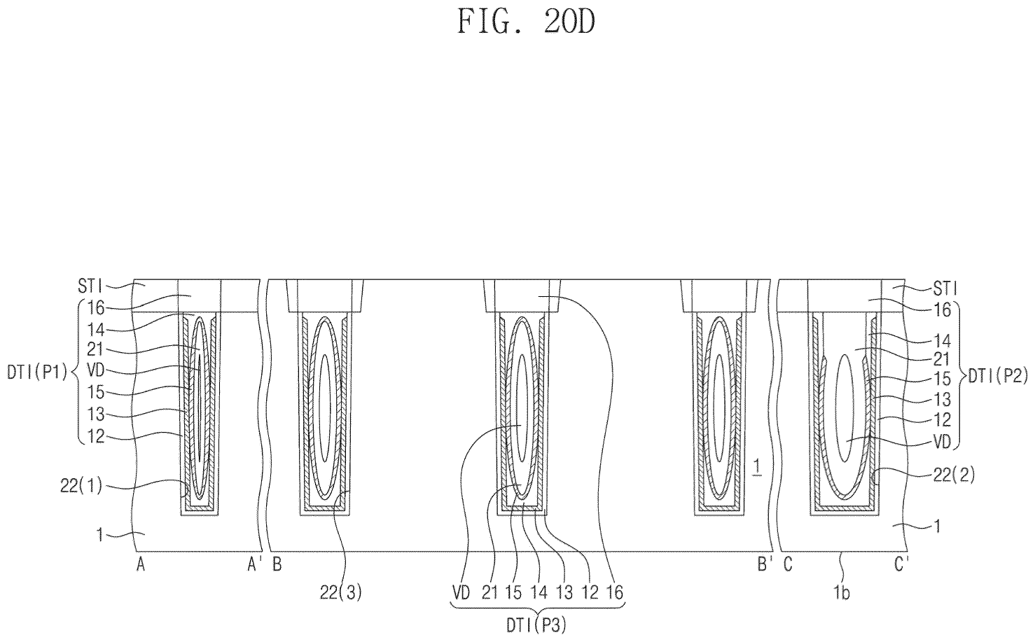

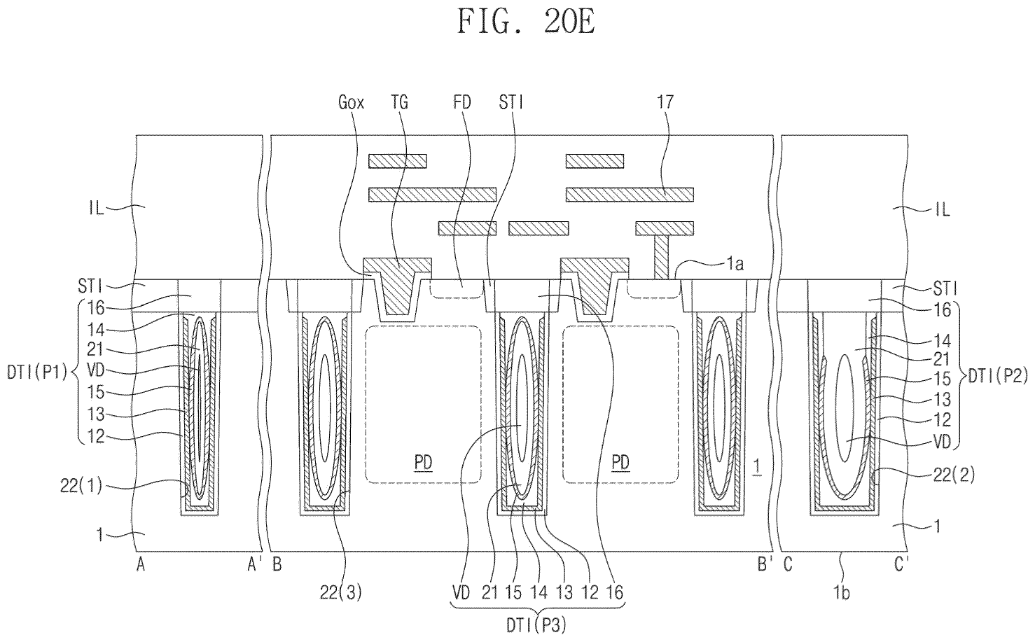

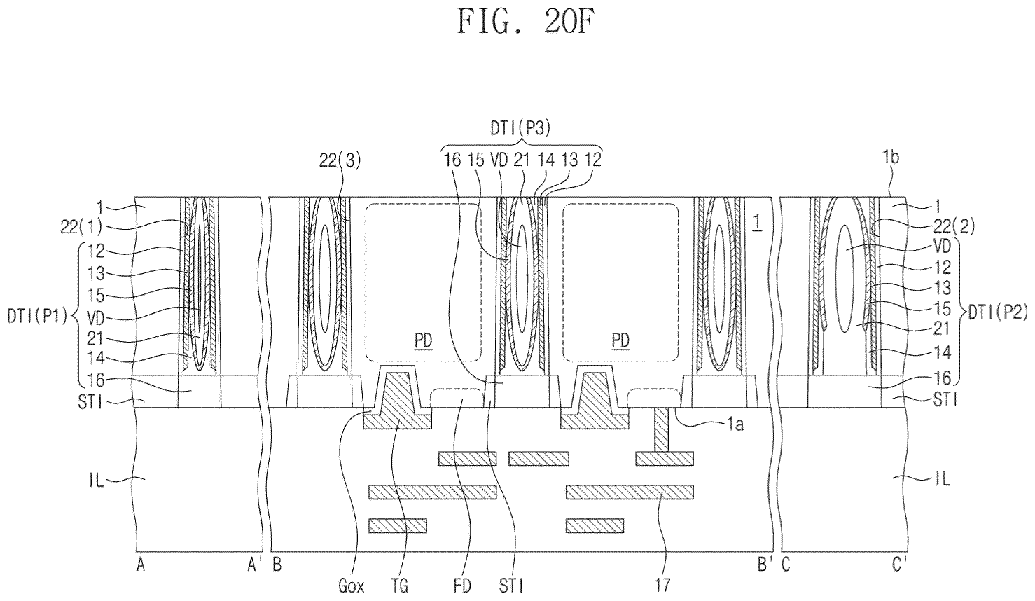

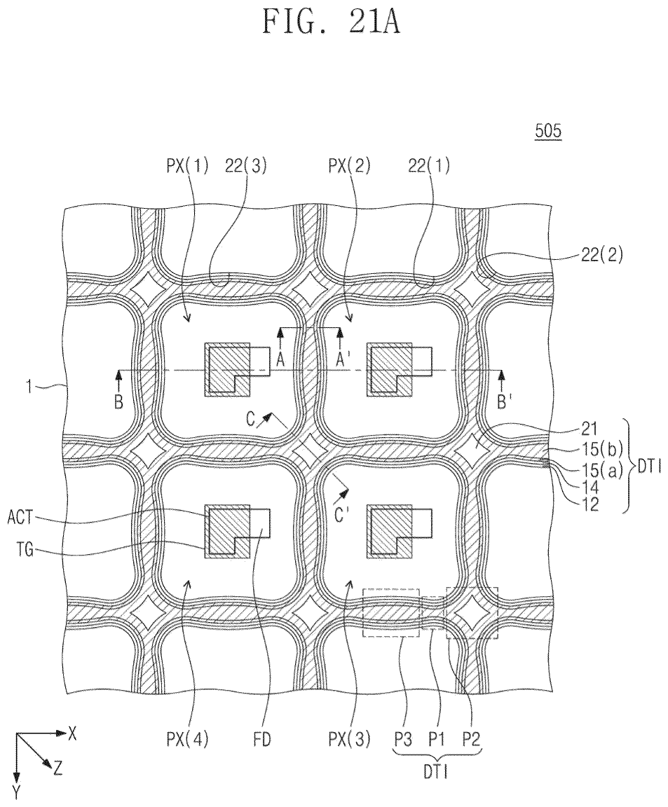

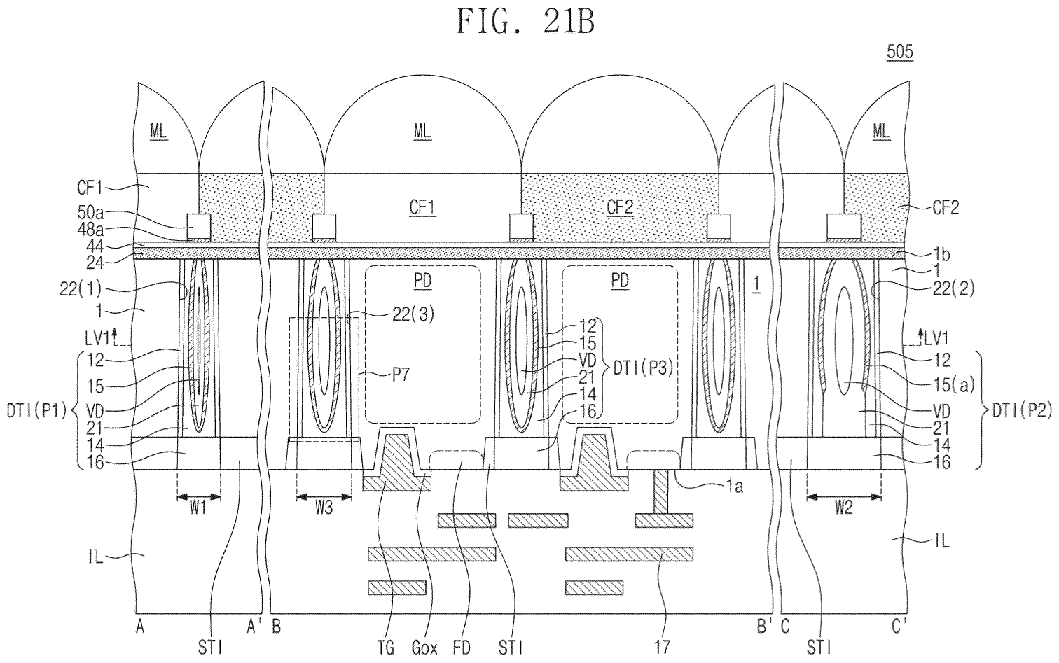

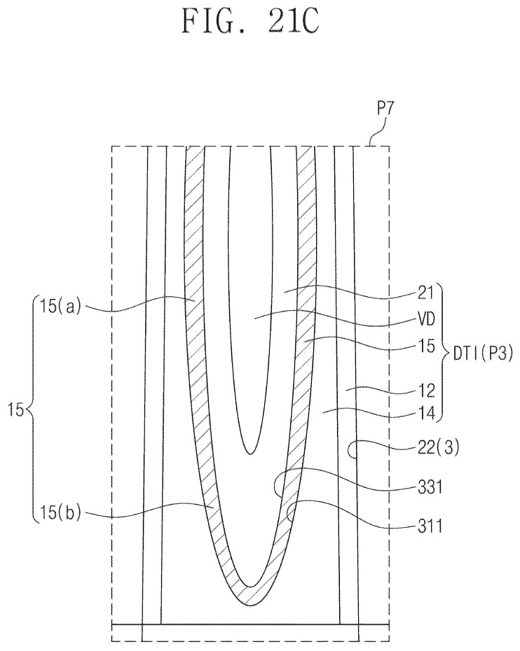

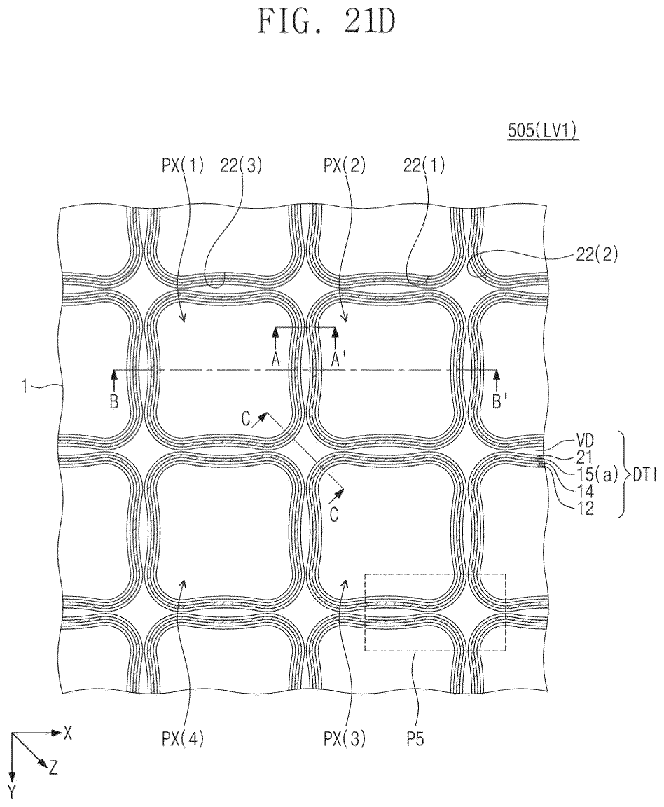

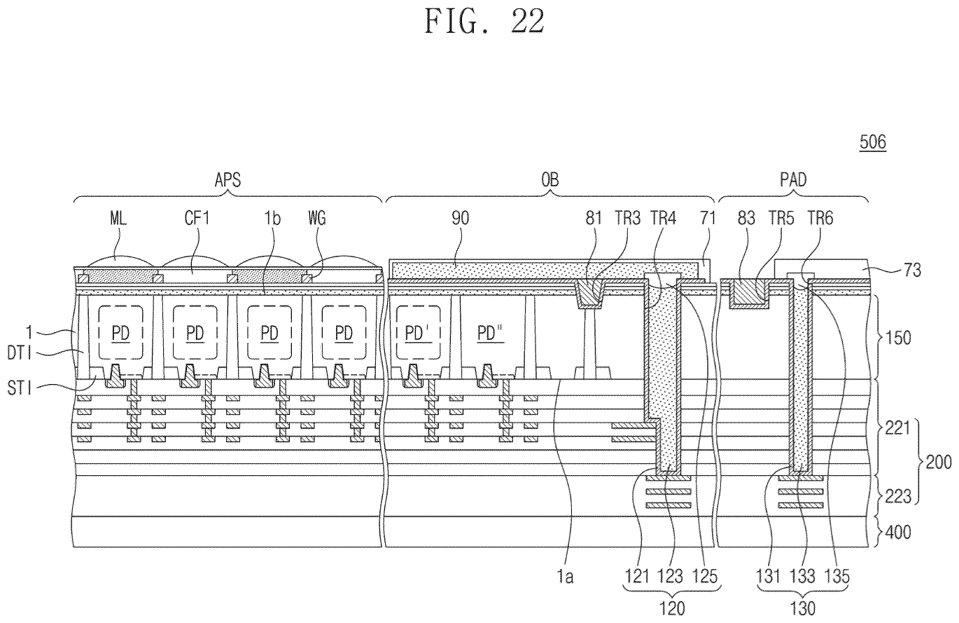

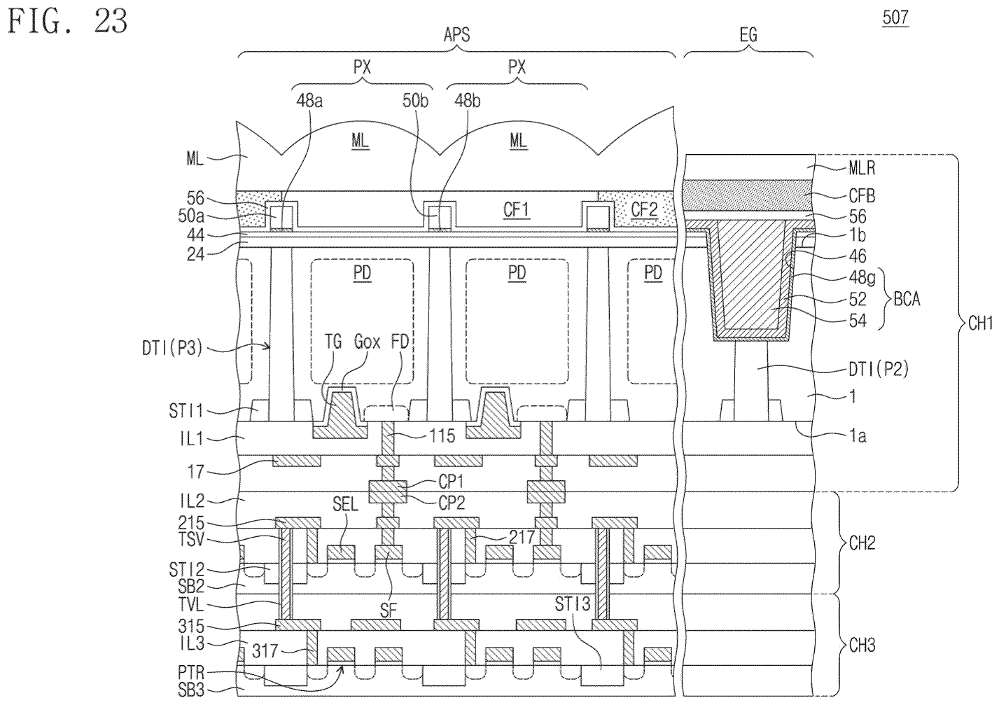

Referring to FIG. 20A, an anisotropic etching process is performed on the second silicon-containing layer 15a. As a result, while the second silicon-containing layer 15a on an upper surface of the first buried insulating layer 14a is removed and the upper surface of the first buried insulating layer 14a is exposed, the second silicon-containing pattern 15 may be formed. The second silicon-containing pattern 15 is formed on the inner wall of the first hole HL and the inner wall of the second empty space 331.

Referring to FIGS. 5B and 20B, the second buried insulating layer 21a is deposited on the first buried insulating layer 14a. The second buried insulating layer 21a may be formed through a process with lower step coverage characteristics than ALD, for example, a CVD process. The second buried insulating layer 21a may be formed on the inner wall of the first hole HL and may also be formed in the second empty space 331 through the first hole HL. In this case, a void region VD may be formed in the second buried insulating layer 21a in the relatively narrow first and third deep trenches 22(1) and 22(3). The void region VD may be connected to the first hole HL as shown in FIG. 5B.

Referring to FIG. 20C, an etch-back process is performed on the second buried insulating layer 21a, the first buried insulating layer 14a, and the insulating liner layer 12a to remove the second buried insulating layer 21a, the first buried insulating layer 14a, and the insulating liner layer 12a on the top surface and sidewalls of the second mask pattern 7, thereby forming an insulating liner pattern 12, a first silicon-containing pattern 13, a first buried insulating pattern 14, a second silicon-containing pattern 15 and a second buried insulating pattern 21 in the deep trench 22. A third buried insulating layer 16a is formed on the second mask pattern 7 to fill the upper portion of the deep trench 22. The third buried insulating layer 16a may be formed as a single-layer or multi-layer structure of at least one of silicon oxide, silicon nitride, silicon oxynitride, and silicon carbonitride.

An annealing process may be additionally performed to crystallize the first and second silicon-containing patterns 13 and 15. In this case, the first impurities (e.g., boron) doped inside the first silicon-containing pattern 13 may diffuse into the second silicon-containing pattern 15.

Referring to FIG. 20D, a Chemical Mechanical Polishing (CMP) process is performed to remove the second mask pattern 7 and the third buried insulating layer 16a on the first mask pattern 9, thereby forming a pixel separation part DTI in the deep trench 22. In the CMP process, the first mask pattern 9 may function as a polishing stop layer. A portion of the second mask pattern 7 may remain and become a device isolation part STI. Then, the first mask pattern 9 is removed and the front surface 1a of the first substrate 1 is exposed.

Referring to FIG. 20E, an ion implantation process is performed on the first substrate 1 to form a photoelectric converter PD. A transfer gate TG, a gate insulating layer Gox, and a floating diffusion region FD are formed on the front surface 1a of the first substrate 1. A first interlayer insulating layer IL and first wirings 17 are formed on the front surface 1a of the first substrate 1.

Referring to FIG. 20F, a back grinding process is performed on the back surface 1b of the first substrate 1 to remove a portion of the first substrate 1 and a portion of the pixel separation part DTI. As a result, the first and second silicon-containing patterns 13 and 15 and the first and second buried insulating patterns 14 and 21 of the pixel separation part DTI may be exposed. In this case, depending on the progress of the back grinding process, the void region VD of the pixel separation part DTI may be exposed. Additionally, the first buried insulating pattern 14 adjacent to the back surface 1b may be removed, leaving the first buried insulating pattern 14 only in a lower portion of the deep trench 22.

Subsequently, referring to FIG. 3B, through a typical process, a fixed charge layer 24, a first protective layer 44, a light-shielding grid pattern 48a, and a low-refractive index pattern 50a, color filters CF1 and CF2, and micro lenses ML are formed on the back surface 1b of the first substrate 1.

FIG. 21A is a top plan view of an image sensor according to embodiments. FIG. 21B is a cross-sectional view of the image sensor taken along lines A-A′, B-B′, and C-C′ of FIG. 21A according to embodiments. FIG. 21C is an enlarged view of portion ‘P7’ in FIG. 21B. FIG. 21D is a top view at a first level of the image sensor of FIG. 21B.

Referring to FIGS. 21A to 21D, in an image sensor 505 according to the present example, a pixel separation part DTI may exclude the first silicon-containing pattern 13 of FIG. 3B. In detail, the pixel separation part DTI according to the present example includes an insulating liner pattern 12, a first buried insulating pattern 14, a second silicon-containing pattern 15, a second buried insulating pattern 21, and a third buried insulating pattern 16.

The insulating liner pattern 12 is in contact with a sidewall of the first substrate 1 in the deep trench 22. The first buried insulating pattern 14 may be in contact with the insulating liner pattern 12. When the first buried insulating pattern 14 and the insulating liner pattern 12 are formed of the same material, an interface therebetween may not be distinguished, and the first buried insulating pattern 14 and the insulating liner pattern 12 may be connected to each other to be formed in an integrated form. The first buried insulating pattern 14 has a first empty space 311 therein. The first empty space 311 may be vertically elongated.

The second silicon-containing pattern 15 is disposed in the first empty space 311 of the first buried insulating pattern 14 and conformally covers the inner wall of the first buried insulating pattern 14. The second silicon-containing pattern 15 may be formed of a boron-doped silicon layer. Alternatively, the second silicon-containing pattern 15 may be formed of boron-doped silicon germanium, SiC, or SiGe:C. A negative bias voltage may be applied to the second silicon-containing pattern 15. The second silicon-containing pattern 15 may serve as a common bias line.

The second silicon-containing pattern 15 may have a ‘U’-shaped cross section. The second silicon-containing pattern 15 may include side parts 15(a) and a connecting part 15(b). In the present example, the side parts 15(a) of the second silicon-containing pattern 15 may be adjacent to the sidewall of the first substrate 1 and may surround each of the pixels PX as shown in FIG. 21B. The side parts 15(a) of the second silicon-containing pattern 15 may be curved to protrude toward a sidewall of the first substrate 1 and may have an arc shape. A first buried insulating pattern 14 may be interposed between the side parts 15(a) of the second silicon-containing pattern 15 and the insulating liner pattern 12. Alternatively, the side parts 15(a) of the second silicon-containing pattern 15 may be in contact with the insulating liner pattern 12. The connecting part 15(b) of the second silicon-containing pattern 15 may connect the side parts 15(a) and may be adjacent to the front surface 1a of the first substrate 1. A lower surface of the connecting part 15(b) may protrude toward the front surface 1a of the first substrate 1 and may be rounded.

The second silicon-containing pattern 15 may have a second empty space 331 therein. The second empty space 331 may be vertically elongated. The second buried insulating pattern 21 is disposed in the second empty space 331 of the second silicon-containing pattern 15. The second buried insulating pattern 21 may include a void region VD.

The second buried insulating pattern 21 may penetrate the second silicon-containing pattern 15 to be adjacent to the front surface 1a at the intersection point that is a center of four adjacent pixels PX(1) to PX(4) (i.e., between the first pixel PX(1) and the third pixel PX(3), or in the second deep trench 22(2) having the widest width W2). In this position, the second silicon-containing pattern 15 includes only the side part 15(a) and excludes the connecting part 15(b). Other configurations may be the same/similar to those described above.

The image sensor 505 of FIGS. 21A to 21D may be manufactured by omitting the manufacturing process of the first silicon-containing pattern 13 of FIGS. 15A and 15B during the manufacturing process of FIGS. 12A to 20F and proceeding with the remaining processes. In this case, as the manufacturing process of the first silicon-containing pattern 13 is omitted, the process may be simplified.

FIG. 22 is a cross-sectional view of an image sensor according to embodiments.

Referring to FIG. 22, an image sensor 506 according to the present example includes a first substrate 1 having a pixel array region APS, an optical black region OB, and a pad region PAD, a wiring layer 200 on a front surface 1a of the first substrate 1, and a second substrate 400 on the wiring layer 200. The wiring layer 200 may include an upper wiring layer 221 and a lower wiring layer 223. The pixel array region APS may include a plurality of pixels PX. The pixels PX disposed in the pixel array region APS may be substantially the same as those previously described with reference to FIGS. 3A to 11 and 21A to 21D.

A light shielding pattern WG, a first connection structure 120, a first conductive pad 81, and a bulk color filter 90 may be provided on the first substrate 1 in the optical black region OB. The first connection structure 120 may include a first connection line 121, an insulating pattern 123, and a first capping pattern 125.

A portion of the first connection line 121 may be provided on a back surface 1b of the first substrate 1. The light shielding pattern WG may cover the back surface 1b and may conformally cover inner walls of a third trench TR3 and a fourth trench TR4. The first connection line 121 may pass through a photoelectric conversion layer 150 and the upper wiring layer 221 to connect the photoelectric conversion layer 150 and the wiring layer 200. In detail, the first connection line 121 may be in contact with the wirings in the upper wiring layer 221 and the lower wiring layer 223, and the first and second silicon-containing patterns 13 and 15 of the pixel separation part DTI in the photoelectric conversion layer 150. Accordingly, the first connection structure 120 may be electrically connected to wirings in the wiring layer 200. The first connection line 121 may include a metal material, such as tungsten. The light shielding pattern WG may block light incident into the optical black region OB.

The first conductive pad 81 may be provided inside the third trench TR3 to fill the remaining portion of the third trench TR3. The first conductive pad 81 may include a metal material, such as aluminum. The first conductive pad 81 may be connected to the first and second silicon-containing patterns 13 and 15 of FIG. 3B. A negative bias voltage may be applied to the first and second silicon-containing patterns 13 and 15 of FIG. 3B through the first conductive pad 81. This may prevent/reduce white spots or dark current problems.

The insulating pattern 123 may fill the remaining portion of the fourth trench TR4. The insulating pattern 123 may fully or partially penetrate the photoelectric conversion layer 150 and the wiring layer 200. A first capping pattern 125 may be provided on an upper surface of the insulating pattern 123. The first capping pattern 125 may be provided on the insulating pattern 123.

A bulk color filter 90 may be provided on the first conductive pad 81, the light shielding pattern WG, and the first capping pattern 125. The bulk color filter 90 may cover the first conductive pad 81, the light shielding pattern WG, and the first capping pattern 125. A first protective layer 71 may be provided on the bulk color filter 90 to seal the bulk color filter 90.

A photoelectric conversion region PD′ and a dummy region PD″ may be provided in the optical black region OB of the first substrate 1. For example, the photoelectric conversion region PD′ may be doped with impurities of a second conductivity type different from the first conductivity type. The second conductivity type may be, for example, N-type. The photoelectric conversion region PD′ has a similar structure to the photoelectric conversion region PD, but may not perform the same operation (i.e., receiving light and generating an electrical signal) as the photoelectric conversion region PD. The dummy region PD″ may not be doped with impurities. A signal generated in the dummy region PD″ may be indicative of information that may be subsequently used to remove process noise.

In the pad region PAD, a second connection structure 130, a second conductive pad 83, and a second protective layer 73 may be provided on the first substrate 1. The second connection structure 130 may include a second connection line 131, an insulating pattern 133, and a second capping pattern 135.

The second connection line 131 may be provided on the back surface 1b of the first substrate 1. In detail, the second connection line 131 may cover the back surface 1b and may conformally cover inner walls of a fifth trench TR5 and a sixth trench TR6. The second connection line 131 may pass through the photoelectric conversion layer 150 and the upper wiring layer 221 to connect the photoelectric conversion layer 150 and the wiring layer 200. In detail, the second connection line 131 may be in contact with wiring in the lower wiring layer 223. Accordingly, the second connection structure 130 may be electrically connected to the wirings in the wiring layer 200. The second connection line 131 may include a metal material, such as tungsten.

The second conductive pad 83 may be provided inside the fifth trench TR5 to fill the remaining portion of the fifth trench TR5. The second conductive pad 83 may include a metal material, such as aluminum. The second conductive pad 83 may serve as an electrical connection path with the outside of an image sensor device. The insulating pattern 133 may fill the remaining portion of the sixth trench TR6. The insulating pattern 133 may fully or partially penetrate the photoelectric conversion layer 150 and the wiring layer 200. The second capping pattern 135 may be provided on the insulating pattern 133.

FIG. 23 is a cross-sectional view of an image sensor according to embodiments.

Referring to FIG. 23, an image sensor 507 according to the present example may have a structure in which first to third sub-chips CH1 to CH3 are sequentially bonded. The first sub-chip CH1 may preferably perform an image sensing function. The first sub-chip CH1 may be the same/similar to those described with reference to FIGS. 3A to 11.

The first sub-chip CH1 may include transfer gates TG on a front surface 1a of a first substrate 1 and first interlayer insulating layers IL1 covering the transfer gates TG. The first substrate 1 may include a pixel array region APS and an edge region EG. The pixel array region APS may include a plurality of unit pixels PX. The edge region EG may correspond to a portion of the optical black region OB in FIG. 22.

A first device isolation part STI1 is disposed on the first substrate 1 to define active regions. A pixel separation part DTI is disposed on the first substrate 1 to separate/define unit pixels PX in the pixel array region APS. The pixel separation part DTI may extend to the edge region EG. The pixel separation part DTI may be the same/similar to that described with reference to FIGS. 3A to 11 and 21A to 21D.

The front surface 1a of the first substrate 1 may be covered with first interlayer insulating layers IL1. First wirings 17 may be disposed between or in the first interlayer insulating layers IL1. A floating diffusion region FD may be connected to a first wirings 17 by a first contact plug 115. A first conductive pad CP1 may be disposed in the lowermost first interlayer insulating layer IL1. The first conductive pad CP1 may include copper.

In the edge region EG, a connection contact BCA may penetrate a first protective layer 44, a fixed charge layer 24, and a portion of the first substrate 1 to be in contact with first and second silicon-containing patterns 13 and 15. The connection contact BCA may be disposed in a third trench 46. The connection contact BCA may include an anti-diffusion pattern 48g that conformally covers an inner sidewall and a bottom surface of the third trench 46, a first metal pattern 52 on the anti-diffusion pattern 48g, and a second metal pattern 54 that fills the third trench 36. The anti-diffusion pattern 48g may include titanium, for example. The first metal pattern 52 may include, for example, tungsten. The second metal pattern 54 may include aluminum, for example. The anti-diffusion pattern 48g and the first metal pattern 52 may extend onto the first protective layer 44 and be electrically connected to other wirings or vias/contacts. The connection contact BCA may be in contact with the second silicon-containing pattern 15 of the pixel separation part DTI of FIGS. 3A to 11 and 21A to 21D. A portion of the connection contact BCA may be inserted into a void region VD of the pixel separation part DTI of FIGS. 3A to 11 and 21A to 21D.

A second protective layer 56 is deposited on the first protective layer 44. The second protective layer 56 may formally cover the light shielding grid pattern 48a, the low-refractive pattern 50a, and the connection contact BCA.

A first optical black pattern CFB may be disposed on the second protective layer 56 in the edge region EG. For example, the first optical black pattern CFB may include the same material as the blue color filter.

A lens residual layer MLR may be disposed on the first optical black pattern CFB in the edge region EG. The lens residual layer MLR may include the same material as the micro lenses ML.

The second sub-chip CH2 may include a second substrate SB2, select gates SEL, source follower gates SF, and reset gates disposed thereon, and a second interlayer insulating layer IL2 covering them. A second device isolation part STI2 is disposed on the second substrate SB2 to define active regions. Second contacts 217 and second wirings 215 may be disposed in the second interlayer insulating layers IL2. A second conductive pad CP2 may be disposed in the uppermost second interlayer insulating layer IL2. The second conductive pad CP2 may include copper. The second conductive pad CP2 may be in contact with the first conductive pad CP1. The source follower gates SF may each be connected to the floating diffusion regions FD of the first sub-chip CH1.

The third sub-chip CH3 may include a third substrate SB3, peripheral transistors PTR disposed thereon, and third interlayer insulating layers IL3 covering them. A third device isolation part STI3 is disposed on the third substrate SB3 to define active regions. Third contacts 317 and third wirings 315 may be disposed in the third interlayer insulating layers IL3. The uppermost third interlayer insulating layer IL3 is in contact with the second substrate SB2. A through electrode TSV may penetrate the second interlayer insulating layer IL2, the second device isolation part STI2, the second substrate SB2, and the third interlayer insulating layer IL3 to connect a second wiring 215 to a third wiring 315. A sidewall of the through electrode TSV may be surrounded by a via insulating layer TVL. The third sub-chip CH3 may include circuits for driving the first and/or second sub-chips CH1 and CH2 or storing electrical signals generated from the first and/or second sub-chips CH1 and CH2.

In the image sensor according to embodiments, in the pixel separation part, the first silicon-containing pattern and/or the second silicon-containing pattern that serves as the common bias exists in the form of a liner. As a result, the portion occupied by silicon in the pixel separation part may be relatively small. Additionally, the second silicon-containing pattern penetrates the second buried insulating pattern at the intersection point between the four pixels, so that the second silicon-containing pattern does not exist at the intersection point. As a result, the light absorption and the light loss due to silicon may be reduced, and the light sensitivity may be improved to form the image sensor with clear image quality.

While aspects of embodiments have been particularly shown and described, it will be understood that various changes in form and details may be made therein without departing from the spirit and scope of the following claims.

What is claimed is:

1. An image sensor comprising:
a substrate having a first surface and a second surface opposite to the first surface; and
a pixel separation structure in the substrate, the pixel separation structure separating pixels of the image sensor from each other,
wherein the pixels comprise first and second pixels spaced apart from each other along a first direction,
wherein the pixel separation structure comprises:
first silicon-containing patterns surrounding each of the first and second pixels when viewed in a plan view and being spaced apart from each other; and
a second silicon-containing pattern extending between the first and second pixels and connecting the first silicon-containing patterns to each other, and
wherein the second silicon-containing pattern comprises side portions adjoining the first silicon-containing patterns, and a connecting portion spaced apart from the first silicon-containing patterns and connecting the side portions.

2. The image sensor of claim 1, further comprising a transistor on the first surface,
wherein the connecting portion has a rounded lower surface that protrudes toward the first surface.

3. The image sensor of claim 1, wherein the pixel separation structure further comprises a first buried insulating pattern between the connecting portion and the first silicon-containing patterns.

4. The image sensor of claim 3, wherein the second silicon-containing pattern has a hollow shell shape, and
wherein the pixel separation structure further comprises a second buried insulating pattern in the second silicon-containing pattern.

5. The image sensor of claim 4, wherein the pixel separation structure defines a void region in the second buried insulating pattern.

6. The image sensor of claim 4, wherein the pixel separation structure further comprises a remaining pattern in the second buried insulating pattern, and
wherein the remaining pattern is formed of a material different from a material of the second buried insulating pattern.

7. The image sensor of claim 6, further comprising a fixed charge layer covering the second surface,
wherein the remaining pattern and the fixed charge layer comprise a common material.

8. The image sensor of claim 1, wherein the first silicon-containing patterns comprise a first concentration of boron, and
wherein the second silicon-containing pattern comprises a second concentration of boron, the second concentration being equal to or less than the first concentration.

9. The image sensor of claim 1, further comprising a natural oxide layer between the first silicon-containing patterns and the second silicon-containing pattern,
wherein the natural oxide layer has a thickness of 1 Å to 5 Å.

10. The image sensor of claim 1, wherein the first silicon-containing patterns comprise first silicon grains of a first average diameter, and
wherein the second silicon-containing pattern comprises second silicon grains of a second average diameter that is equal to or greater than the first average diameter.

11. The image sensor of claim 1, wherein the pixels further comprise a third pixel spaced apart from the second pixel in a second direction intersecting the first direction,
wherein the pixel separation structure is between the first to third pixels,
when viewed in a plan view, the pixel separation structure further comprises:
a first separation portion between a corner of the first pixel and a corner of the second pixel adjacent to the corner of the first pixel;
a second separation portion between the corner of the first pixel and a corner of the third pixel adjacent to the corner of the first pixel; and
a third separation portion between a center of the first pixel and a center of the second pixel adjacent to the center of the first pixel,
wherein the first to third separation portions comprise the first silicon-containing patterns,
wherein the first separation portion comprises the second silicon-containing pattern, and
wherein the second silicon-containing pattern is offset from the third separation portion.

12. The image sensor of claim 11, wherein the first separation portion has a first width in the first direction,
wherein the second separation portion has a second width that is wider than the first width in the second direction, and
wherein the third separation portion has a third width that is wider than the first width but narrower than the second width in the first direction.

13. The image sensor of claim 11, wherein the third separation portion further comprises a first buried insulating pattern between the first silicon-containing patterns, and
wherein a void region is defined in the first buried insulating pattern.

14. An image sensor comprising:
a substrate having a first surface and a second surface opposite to the first surface;
a transistor on the first surface; and
a pixel separation structure in the substrate, the pixel separation structure separating pixels of the image sensor from each other,
wherein the pixels comprise first to fourth pixels arranged in a clockwise direction,
wherein the pixel separation structure comprises:
first silicon-containing patterns surrounding the first to fourth pixels when viewed in a plan view and spaced apart from each other;
a second silicon-containing pattern connecting the first silicon-containing patterns adjacent to each other; and
a first buried insulating pattern spaced apart from the first silicon-containing patterns,
wherein the second silicon-containing pattern extends between the first buried insulating pattern and the first silicon-containing patterns, and
wherein the first buried insulating pattern penetrates the second silicon-containing pattern between a corner of the first pixel and a corner of the third pixel adjacent thereto.

15. The image sensor of claim 14, wherein the second silicon-containing pattern comprises side portions and a connecting portion, the side portions adjoining the first silicon-containing patterns, and the connecting portion being spaced apart from the first silicon-containing patterns and connecting the side portions, and
wherein the pixel separation structure further comprises a second buried insulating pattern between the connecting portion and the first silicon-containing patterns.

16. The image sensor of claim 15, wherein the first buried insulating pattern is adjacent to an upper surface of the connecting portion between a center of the first pixel and a center of the second pixel adjacent to the center of the first pixel.

17. An image sensor comprising:
a substrate having a first surface and a second surface opposite to the first surface; and
a pixel separation structure in the substrate, the pixel separation structure separating pixels of the image sensor from each other,
wherein the pixels comprise first and second pixels spaced apart from each other in a first direction, and
wherein the pixel separation structure comprises:
a first buried insulating pattern between the first and second pixels and defining a first empty space inside of the first buried insulating pattern, the first empty space being vertically elongated;
a silicon-containing pattern covering an inner wall of the first buried insulating pattern in the first empty space, having a ‘U’-shaped cross-section, and defining a second empty space; and
a second buried insulating pattern in the second empty space.

18. The image sensor of claim 17, further comprising:
a transfer gate on the first surface; and
a fixed charge layer on the second surface,
wherein the pixels further comprise a third pixel spaced apart from the second pixel in a second direction crossing the first direction,
wherein the pixel separation structure extends between the first pixel and the third pixel, and
wherein the second buried insulating pattern penetrates the silicon-containing pattern to be adjacent to the first surface between the first pixel and the third pixel.

19. The image sensor of claim 17, further comprising an insulating liner pattern between the first buried insulating pattern and the substrate.

20. The image sensor of claim 17, further comprising:
a transfer gate on the first surface; and
a fixed charge layer on the second surface,
wherein the silicon-containing pattern comprises:
side portions adjacent to a side surface of the substrate and surrounding each of the first and second pixels; and
a connecting portion connecting the side portions and being adjacent to the first surface, and
wherein each of the side portions has an arc shape which protrudes toward the side surface of the substrate.
